(19) United States
(12) Patent Application Publication
(10) Pub. No.: US 2026/0165036 A1
(43) Pub. Date: Jun. 11, 2026

(54) TUNNEL JUNCTIONS AND METHODS OF USING THE SAME

(71) Applicant: University of Washington, Seattle, WA (US)

(72) Inventors: John CENKER, Seattle, WA (US); Xiaodong XU, Seattle, WA (US)

(73) Assignee: University of Washington, Seattle, WA (US)

(21) Appl. No.: 18/881,330

(22) PCT Filed: Aug. 4, 2023
(86) PCT No.: PCT/US2023/071658

§ 371 Date: Jan. 6, 2025

Related U.S. Application Data
(60) Provisional application No. 63/396,071, filed on Aug. 8, 2022.

(51) Int. Cl. H10N 60/80; H10N 60/12; H10N 60/85

(52) U.S. Cl. CPC H10N 60/805; H10N 60/12; H10N 60/85

(57) ABSTRACT

Strain-programmable tunneling resistance devices and systems for inducing changes in tunneling magnetoresistance are described. In an embodiment, the tunneling resistance device includes an insulating barrier layer comprising a van der Waals semiconductor, two or more electrical contacts in electrically conductive communication with opposing sides of the insulating barrier layer, and a flexible substrate coupled to a surface of the insulating barrier layer. In an embodiment, the van der Waals semiconductor is an A-type van der Waals antiferromagnet. In an embodiment, the system includes a tunneling resistance device coupled to a piezoelectric strain cell and apply a voltage to induce strain in the insulating barrier layer.

### CROSS-REFERENCE TO RELATED APPLICATION

This application claims the benefit of U.S. patent application Ser. No. 63/396,071, filed on Aug. 8, 2022, the disclosure of which is hereby incorporated by reference in its entirety.

### STATEMENT OF GOVERNMENT LICENSE RIGHTS

This invention was made with government support under Grant No. MURI no. FA9550-19-1-0390, awarded by the Air Force Office of Scientific Research (AFOSR/JA) and Grant No. DE-SC0018171, awarded by the U.S. Department of Energy. The government has certain rights in the invention.

### TECHNICAL FIELD

This disclosure relates generally to spintronic devices, particularly for controlling electron tunneling through magnetic layers. Also described herein are methods of controlling the energetics of such devices.

### BACKGROUND INFORMATION

The control and readout of discrete magnetic states lies at the foundation of the field of spintronics and modern information storage. Standard spintronic devices utilize the spin filtering phenomenon, where spin-selective transport processes, such as electron tunneling through magnetic layers, creates spin polarization and magnetoresistance. Controlling the energetics of the magnets in such devices, known as magnetic tunnel junctions (MTJs), has enabled many important technological advancements. For instance, switching from anti-parallel (AP) to parallel (P) magnetic states in stable MTJs drives large changes to the tunneling magnetoresistance (TMR). This behavior is the conceptual basis for magnetic random-access memory (MRAM). On the other hand, when the magnetic layers are thinned so that the energy difference between P and AP states is small, the magnetic order becomes unstable and stochastic switching between the two states is observed. Such unstable p-bits are fundamental building blocks for the emerging fields of probabilistic and neuromorphic computing. Despite the successes of conventional MTJs in both conventional and probabilistic computing schemes, writing the magnetic memory bits tends to rely on energy-intensive means such as the application of large magnetic fields or currents. Moreover, since the stability of the MTJ is fixed by the growth thickness, it is difficult to switch from stable MRAM operation to unstable p-bit functionality in the same device.

### BRIEF DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1A is a perspective view of a tunneling resistance device in accordance with an embodiment of the present disclosure;

FIG. 1B is a plan view of the device of FIG. 1A in accordance with an embodiment of the present disclosure;

FIG. 1C is a cross-sectional side view of the tunneling resistance device taken along a line at substantially the midpoint of the width of the device of FIG. 1B in accordance with an embodiment of the present disclosure;

FIG. 1D is a cross-sectional side view of the tunneling resistance device taken along a line at substantially the midpoint of the length of the device of FIG. 1B in accordance with an embodiment of the present disclosure;

FIG. 2A is a perspective view of a piezoelectric strain cell physically coupled with a tunneling resistance device and operatively coupled to a controller, in accordance with an embodiment of the present disclosure;

FIG. 2B is a plan view of the piezoelectric strain cell of FIG. 2A in accordance with an embodiment of the present disclosure;

FIG. 2C is a cross-sectional side view of the piezoelectric strain cell taken along a line at substantially the midpoint of the width of the device of FIG. 2B in accordance with an embodiment of the present disclosure;

FIG. 2D is a cross-sectional side view of the tunneling resistance device taken along a line at substantially the midpoint of the length of the device of FIG. 2B in accordance with an embodiment of the present disclosure;

FIG. 3A is a schematic of the magnetic state evolution of the insulating barrier layer in a tunneling resistance device in accordance with an embodiment of the present disclosure with the application of either magnetic fields along the easy b axis or in-plane uniaxial strain;

FIG. 3B is a schematic of an embodiment of a tunneling resistance device in accordance with an embodiment of the present disclosure;

FIG. 3C is a schematic illustration of the magnetic field dependence of a tunneling resistance device in accordance with an embodiment of the present disclosure;

FIG. 4A shows magnetoresistance sweeps in accordance with an embodiment of the present disclosure at select piezo voltages with a fixed bias voltage across the tunneling resistance device of V_{B}=0.5 V, in accordance with an embodiment of the present disclosure;

FIG. 4B shows full strain-dependent tunneling magnetoresistance (TMR) in accordance with an embodiment of the present disclosure with the magnetic field swept from positive to negative, demonstrating a rapid drop-off in tunneling resistance at zero magnetic field at intermediate strain (piezo voltage of around 5 V);

FIG. 4C is a strain dependent photoluminescence (PL) intensity plot in accordance with an embodiment of the present disclosure;

FIG. 4D shows the bias dependent tunneling current in accordance with an embodiment of the present disclosure with magnetic fields of 0 T (dashed) and 3 T (solid) applied in the low strain state at a temperature of 60 K with the magnetic state for each curve is depicted in the inset;

FIG. 4E shows the bias dependent tunneling current in accordance with an embodiment of the present disclosure with magnetic fields of 0 T (dashed) and 3 T (solid) applied in the high strain state performed at a temperature of 60 K;

FIG. 5A shows the tunneling resistance as a function of piezo voltage in accordance with an embodiment of the present disclosure with the change in magnetic state from antiferromagnetic (AFM) to ferromagnetic (FM) interlayer coupling is depicted by the inset spin diagram;

FIG. 5B shows the piezo-voltage-dependent tunneling resistance at select temperatures from 30 K (top panel) to 149 K (bottom panel), in accordance with an embodiment of the present disclosure;

FIG. 5C shows the temperature dependence of the TMR ratio, defined as TMR (%)=(Rₐₚ−Rₚ)/Rₚ×100, in accordance with an embodiment of the present disclosure;

FIG. 5D shows the magnetic-field dependent tunneling resistance at 155 K in the low strain (solid) and high strain (dashed) states, in accordance with an embodiment of the present disclosure;

FIG. 6A shows the tunneling current over time as strain pulses of increasing amplitude are applied in accordance with an embodiment of the present disclosure, where the inset shows the measurement scheme;

FIG. 6B shows the tunneling current over time with changes in the static piezo voltage, V_{PDC}, in accordance with an embodiment of the present disclosure;

FIG. 6C is a schematic illustration of strain tuning between magnetic domains in accordance with an embodiment of the present disclosure;

FIG. 6D shows the bias dependence of the switching rate in the metastable state where the piezo voltage is kept constant during the measurement and data from are taken at 60 K, in accordance with an embodiment of the present disclosure;

FIG. 6E is a response function of a sensitive magnetic domain as a function of static piezo voltage at a temperature of 85 K in accordance with an embodiment of the present disclosure, where a value of either 0 or 1 indicates a stable domain;

FIG. 6F shows the fluctuations between parallel and antiparallel configurations, indicating an equal amount of fluctuations between the parallel and antiparallel configuration, in accordance with an embodiment of the present disclosure;

FIG. 6G shows the p-values returned by the NIST random number test suite applied to the binary sequence from FIG. 6F;

FIG. 7A is an optical microscope image of a trilayer CrSBr flake, where crystal inset axes are identified by the anisotropic crystal structure, in accordance with an embodiment of the present disclosure;

FIG. 7B shows an A-type AFM structure in bilayer and thicker CrSBr in accordance with an embodiment of the present disclosure;

FIG. 8A is a schematic illustration showing a piezoelectric strain cell in accordance with an embodiment of the present disclosure used to stretch the flexible substrate;

FIG. 8B is a schematic illustration of a clamping scheme in accordance with an embodiment of the present disclosure;

FIG. 9A shows the magnetic field dependent PL measurements taken along the easy b crystal axis in accordance with an embodiment of the present disclosure;

FIG. 9B shows the magnetic field dependent PL measurements taken along the intermediate a crystal axis in accordance with an embodiment of the present disclosure;

FIG. 9C shows the magnetic field dependent PL measurements taken along the hard c crystal axis in accordance with an embodiment of the present disclosure;

FIG. 9D is a schematic illustration of the exciton spatial distribution (ovals) in AFM and FM states in accordance with an embodiment of the present disclosure;

FIG. 10A shows magneto-PL sweeps with the field applied along the easy axis with a piezo voltage of 0 V, in accordance with an embodiment of the present disclosure;

FIG. 10B shows magneto-PL sweeps with the field applied along the easy axis with a piezo voltage of 60 V, in accordance with an embodiment of the present disclosure;

FIG. 10C shows the extracted spin-flip field as a function of piezo voltage in accordance with an embodiment of the present disclosure;

FIG. 10D shows magneto-PL measurement with the magnetic field swept from positive to negative at a piezo voltage of 110 V, in accordance with an embodiment of the present disclosure;

FIG. 11A shows Raman scattering from the P₃ phonon taken on the insulating barrier layer at a piezo voltage of 0 V, in accordance with an embodiment of the present disclosure;

FIG. 11B is a Raman intensity plot as a function of piezo voltage in accordance with an embodiment of the present disclosure;

FIG. 11C shows the measured strain as a function of the applied piezo voltage to the strain cell in accordance with an embodiment of the present disclosure;

FIG. 12A shows magnetoresistance sweeps in the low strain state at a piezo voltage of 0 V, with magnetoresistance sweeps depicted for down sweeps (dashed lines) and up sweeps (solid lines), in accordance with an embodiment of the present disclosure;

FIG. 12B shows magnetoresistance sweeps in the low-intermediate strain state at a piezo voltage of 10 V, with magnetoresistance sweeps depicted for down sweeps (dashed lines) and up sweeps (solid lines), in accordance with an embodiment of the present disclosure;

FIG. 12C shows magnetoresistance sweeps in the intermediate-high strain state at a piezo voltage of 15 V, with magnetoresistance sweeps depicted for down sweeps (dashed lines) and up sweeps (solid lines), in accordance with an embodiment of the present disclosure;

FIG. 12D shows magnetoresistance sweeps in the high strain state at a piezo voltage of 25 V, with magnetoresistance sweeps depicted for down sweeps (dashed lines) and up sweeps (solid lines), in accordance with an embodiment of the present disclosure;

FIG. 13A shows TMR measurements at a select piezo voltage corresponding to a low-intermediate strain, depicting both down (dashed) and up (solid) sweeps in the magnetic field, in accordance with an embodiment of the present disclosure;

FIG. 13B shows the integrated intensity from magneto-PL measurements at the same piezo voltage as FIG. 13A as the field is swept down (dashed) and up (solid) at a select piezo voltage, in accordance with an embodiment of the present disclosure;

FIG. 13C is an optical image of a device in accordance with the present disclosure with different spots labeled by a circle, a triangle, a square, and a star;

FIG. 13D depicts magneto-PL sweeps at the circular spot in FIG. 13C, where the top panel depicts the down sweep and the bottom panel depicts the up sweep;

FIG. 13E depicts magneto-PL sweeps at the triangular spot in FIG. 13C, where the top panel depicts the down sweep and the bottom panel depicts the up sweep;

FIG. 13F depicts magneto-PL sweeps at the square spot in FIG. 13C, where the top panel depicts the down sweep and the bottom panel depicts the up sweep;

FIG. 13G depicts magneto-PL sweeps at the star spot in FIG. 13C, where the top panel depicts the down sweep and the bottom panel depicts the up sweep;

FIG. 14A shows strain pulse amplitude dependence in the purely FM state in accordance with an embodiment of the present disclosure;

FIG. 14B shows changes in tunneling current over time as a strain pulse of 0.5 V is applied in the AFM state in accordance with an embodiment of the present disclosure;

FIG. 15A shows the tunneling current over time of a metastable domain with a positive bias applied to the magnetic tunnel junction (MTJ) tunneling resistance device, in accordance with an embodiment of the present disclosure;

FIG. 15B shows the tunneling current over time of a metastable domain with a negative bias applied to the tunneling resistance device, in accordance with an embodiment of the present disclosure;

FIG. 15C is a schematic illustration depicting an asymmetric vertical domain structure consistent with the data of FIGS. 15A and 15B;

FIG. 16A is a plot showing magnetoresistance sweeps of a MTJ with a six-layer CrSBr tunnel barrier as the piezo voltage Vₚ is increased from 32.5 V to 75 V, in accordance with an embodiment of the present disclosure;

FIG. 16B shows magnetoresistance sweeps in the low strain AFM state, where the inset is an optical image of the device (scale bar 5 μm), in accordance with an embodiment of the present disclosure;

FIG. 16C shows magnetoresistance sweeps in the high strain FM state in accordance with an embodiment of the present disclosure;

FIG. 16D is a plot of resistance over time at a select piezo voltage in accordance with an embodiment of the present disclosure during the magnetic phase transition, depicting stochastic domain switching;

FIG. 16E is a plot of resistance over time at a select piezo voltage in accordance with an embodiment of the present disclosure during the magnetic phase transition, depicting that the resistance can be stabilized by slightly increasing strain;

FIG. 17A shows a stochasticity analysis of switching data taken near p=0.5 in accordance with an embodiment of the present disclosure;

FIG. 17B shows the dwell time of the data of FIG. 17A, i.e., the time between switches, of the 0 and 1 states, plotted as a histogram for the 0 state, following an exponential envelope as expected for a Poisson process, in accordance with an embodiment of the present disclosure;

FIG. 17C shows the extracted dwell times of the data of FIG. 17A, plotted as a histogram for the 1 state, following an exponential envelope as expected for a Poisson process, in accordance with an embodiment of the present disclosure;

FIG. 17D shows a plot of the logarithm of the histogram bin counts (N) versus the dwell time for the 0 state for the data of FIG. 17A, in accordance with an embodiment of the present disclosure;

FIG. 17E is a plot of the logarithm of the histogram bin counts (N) versus the dwell time for the 1 state for the data of FIG. 17A in accordance with an embodiment of the present disclosure;

FIG. 18 is a block diagram depicting a method for switching an interlayer magnetic coupling from AFM to FM coupling and for measuring resistance in accordance with an embodiment of the present disclosure; and

FIG. 19 is a block diagram depicting a method for operating a random number generator in accordance with an embodiment of the present disclosure.

### DETAILED DESCRIPTION

Embodiments of a device, system, and method for improved tunneling magnetoresistance (TMR) control in magnetic tunnel junctions (MTJs) using van der Waals magnets are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

### Tunneling Resistance Devices

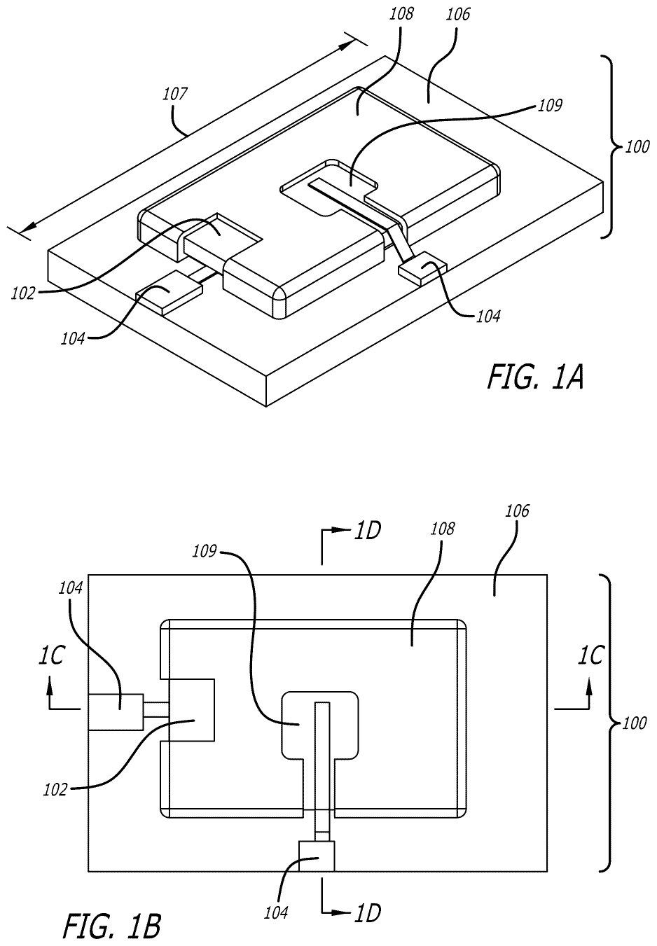

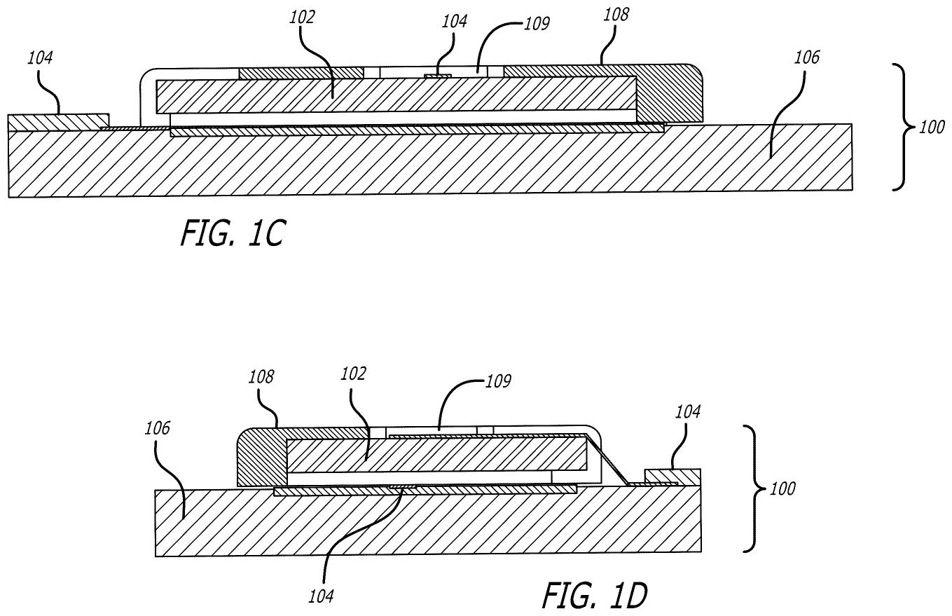

In an aspect, the present disclosure provides an MTJ tunneling resistance device. In this regard, attention is directed to FIGS. 1A-1D in which a tunneling resistance device 100 is illustrated.

FIG. 1A is a perspective view of one representative embodiment of a tunneling resistance device 100 in accordance with an embodiment of the present disclosure. FIG. 1B is a plan view of the tunneling resistance device 100. FIG. 1C is a cross-sectional side view of the tunneling resistance device 100 taken along a line at substantially the midpoint of the width of the device 100. FIG. 1D is a cross-sectional side view of the tunneling resistance device 100 taken along a line at substantially the midpoint of the length of the device 100.

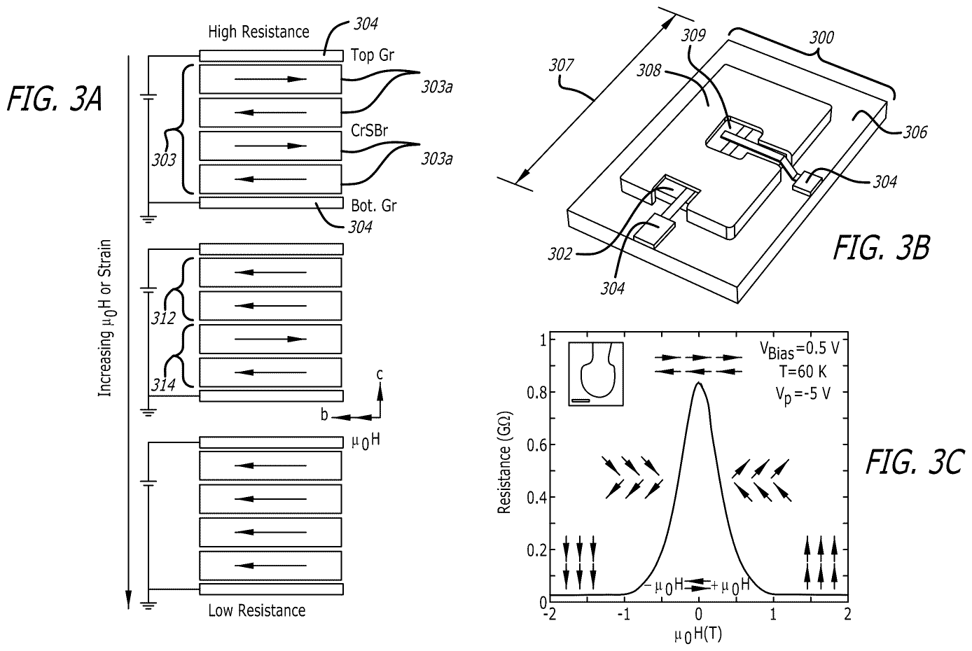

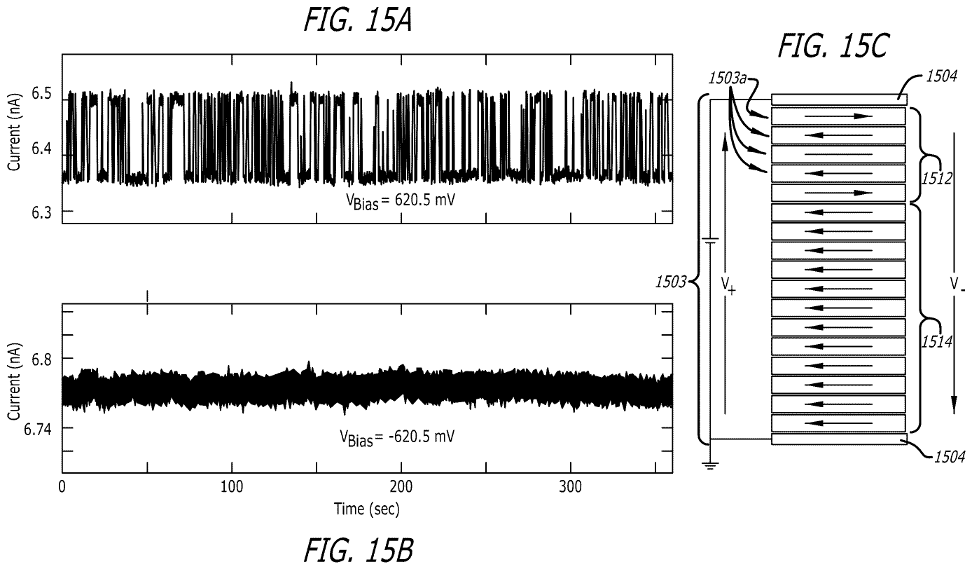

The tunneling resistance device 100 is shown to include an insulating barrier layer 102. In an embodiment, insulating barrier layer 102 is van der Waals semiconductor. In an embodiment, exfoliated van der Waals semiconductor materials are advantageously configured to produce atomically thin magnetic memory and spintronic devices. In an embodiment, MTJs which use van der Waals semiconductors provide programmable and energy efficient memory at single atomic layer limits. In an embodiment, the insulating barrier layer 102 comprises a van der Waals semiconductor that is an A-type van der Waals antiferromagnet. The A-type van der Waals antiferromagnet is a semiconductor where individual monolayers are ferromagnetic (FM) while the interlayer coupling is antiferromagnetic (AFM), as depicted schematically in FIGS. 3A and 15C, discussed further herein below.

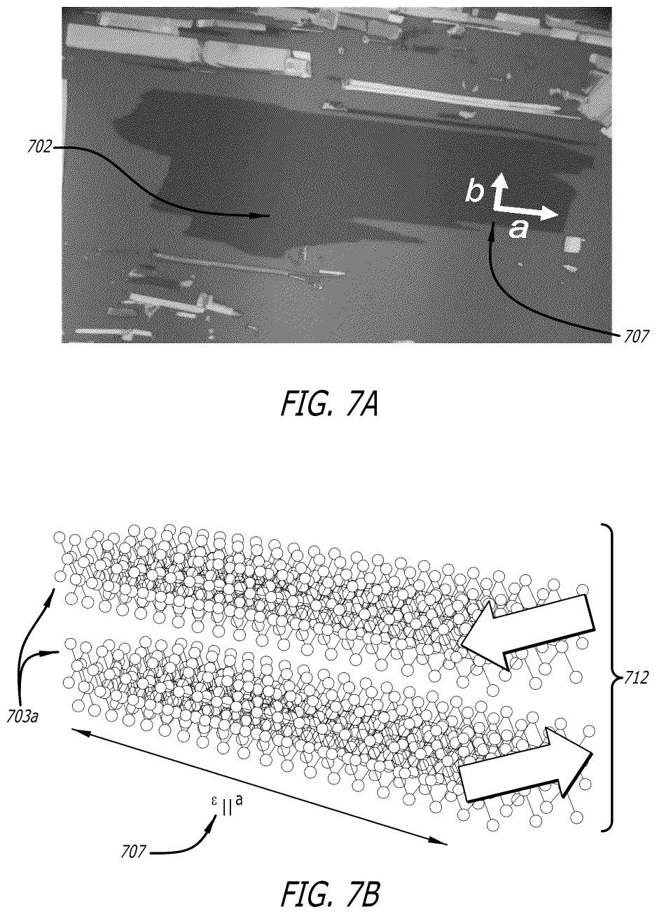

In an embodiment, the insulating barrier layer 102 comprises an A-type van der Waals antiferromagnet, such as an A-type van der Waals antiferromagnet selected from the group comprising CrSBr, CrI₃, CrPS₄, and combinations thereof. In an embodiment, the insulating barrier layer 102 is CrSBr. In an embodiment, bulk CrSBr is exfoliated to the monolayer limit, as shown in FIG. 7A, yielding large rectangular flakes which are air-stable in bilayer and thicker samples. The orthorhombic crystal structure enables easy identification of the crystal axes 707, with the short and long axes corresponding to the b and a axes, respectively. When monolayer CrSBr is cooled, in-plane FM ordering with triaxial magnetic anisotropy onsets below a relatively high Curie temperature of T_{c}˜146 K. The magnetic easy, intermediate, and hard axes are aligned along the b, a, and c crystal axes 707, respectively. When the monolayers are stacked, i.e., in bilayer and thicker flakes, the weak AFM interlayer coupling produces an A-type layered AFM structure, as shown schematically in FIG. 7B, below a relatively high Neel temperature of T_{N}˜132 K. This A-type structure is common to many 2D magnetic materials and is advantageous for use in spintronic devices such as MTJs since the layer-dependent magnetization forms intrinsic, atomically sharp spin filters. In addition to the high ordering temperatures and air stability, CrSBr distinguishes itself from the other 2D magnets due to its semiconducting properties which have been established by scanning tunneling microscopy and electrical transport experiments. In an embodiment, the insulating barrier layer 102 is a rectangular flake defined by an a and b axis, where the b axis is the short axis of the rectangular flake and the a axis is the long axis of the rectangular flake.

Materials tend to break at large defects and dislocations in the crystal lattice. Atomically thin crystals, which have much fewer total defects than the bulk ones, can therefore, survive much larger strains.

Referring still to FIGS. 1A-1D, in an embodiment, the thickness of the insulating barrier layer 102 depends on the number of monolayer planes of the insulating barrier layer 102. In an embodiment, the insulating barrier layer 102 comprises at least two atomically thin monolayer planes. In an embodiment, the insulating barrier layer 102 comprises at least three atomically thin monolayer planes. In an embodiment, the insulating barrier layer 102 comprises at least four atomically thin monolayer planes. In an embodiment, the insulating barrier layer 102 comprises at least five atomically thin monolayer planes. In an embodiment, the insulating barrier layer 102 comprises at least six atomically thin monolayer planes. In an embodiment, the insulating barrier layer 102 comprises at least sixteen atomically thin monolayer planes.

In an embodiment, the insulating barrier layer 102 has a thickness in the range of about 1.4 nm to about 20 nm. In an embodiment, the insulating barrier layer 102 has a thickness in the range of about 3 to about 20 nm. In an embodiment, the insulating barrier layer 102 has a thickness in the range of about 4.5 to about 20 nm. In an embodiment, the insulating barrier layer 102 has a thickness in the range of about 6 to about 20 nm. In an embodiment, the insulating barrier layer 102 has a thickness in the range of about 7.5 to about 20 nm. In an embodiment, the insulating barrier layer 102 has a thickness in the range of about 10 to about 20 nm. In an embodiment, the insulating barrier layer 102 has a thickness in the range of about 1.4 to about 10 nm. An insulating barrier layer 102 with a smaller thickness has the advantage of miniaturization of devices down to the atomically thin limit. A thicker insulating barrier layer 102 has the advantage of comprising more atomically thin sublayers and, as discussed further herein below with respect to FIG. 3A, therefore undergo additional switches in the interlayer coupling between AFM and FM.

FIG. 3A depicts schematically the magnetic state evolution of the van der Waals semiconducting material of the insulating barrier layer 302 in a tunneling resistance device 300, depicted in FIG. 3B. Tunneling resistance device 300 comprises an insulating barrier layer 302 comprising a van der Waals semiconductor; two or more electrical contacts 304 in electrically conductive communication with opposing sides of the insulating barrier layer 302; and a flexible substrate 306 coupled to a surface of the insulating barrier layer 302. In an embodiment, the insulating barrier layer 302 is affixed or otherwise coupled to the flexible substrate 306 by a fastener 308. In an embodiment, the fastener 308 defines an aperture 309 to surround one of the two or more electric contacts 304. In an embodiment, the device 300 is an example of device 100 discussed further herein with respect to FIGS. 1A-1D. With the application of either a) magnetic fields along the easy b crystal axis 307, or b) in-plane uniaxial strain in accordance with an embodiment of the present disclosure, the interlayer coupling between monolayers 303a of the insulating barrier layer 302 switch. The changing magnetic configuration creates different resistance states when bias is applied between the electrical contacts 304. The right and left arrows denote the spin direction within each layer. The top panel of FIG. 3A depicts a layered AFM state of an insulating barrier layer 302 comprising four atomically thin monolayer planes 303 in accordance with an embodiment of the present disclosure. The layered AFM state suppresses the tunneling current at low magnetic field or low in-plane uniaxial strain. The middle panel of FIG. 3A depicts a layered AFM state of an insulating barrier layer 302 in accordance with an embodiment of the present disclosure where an intermediate magnetic field or an intermediate in-plane uniaxial strain has been applied. One interlayer coupling between monolayers 303a has switched to a FM interlayer coupling 314 and one interlayer coupling between monolayers 303a remains in the AFM interlayer coupling 312. The bottom panel of FIG. 3A depicts a layered AFM state of an insulating barrier layer 302 in accordance with an embodiment of the present disclosure, where a large magnetic field or a large in-plane uniaxial strain has been applied. The interlayer coupling between all monolayers 303a has switched to the FM interlayer coupling 312 state.

Referring again to FIG. 1A-1D, tunneling resistance device 100 is shown to include two or more electrical contacts 104 in electrically conductive communication with opposing sides of the insulating barrier layer 102. In an embodiment, the insulating barrier layer 102 has a first side and a second side, where a first electrical contact 104 is in electrically conductive communication with the first side of the insulating barrier layer 102, and a second electrical contact 104 is in electrically conductive communication with the second side of the insulating barrier layer 102, such that the two or more electrical contacts 104 sandwich the insulating barrier layer 102. In an embodiment, each electrical contact 104 of the two or more electrical contacts 104 is in the form of a wire, a sheet, a polygonal plate, or any other suitable form, or any combination thereof. In an embodiment, the two or more electrical contacts 104 have an area co-extensive with the insulating barrier layer 102, an area that is smaller than that of the insulating barrier layer 102, or any combination thereof. In the embodiment illustrated by FIG. 1A-1D, a first electrical contact 104 is in electrically conductive communication with one side of the insulating barrier layer 102 and is oriented along an x-axis, and a second electrical contact 104 is in electrically conductive communication with a second side of the insulating barrier layer 102 and is oriented along a y-axis, such that the second electrical contact 104 is substantially perpendicular to the first electrical contact 104. It is to be understood that the two or more electrical contacts 104 take any orientation with respect to one another and are not limited to a perpendicular orientation. In an embodiment, the two or more electrical contacts 104 are graphite. In another embodiment, the two or more electrical contacts 104 are superconducting electrical contacts. Replacing the graphite contacts with or otherwise using superconducting ones enables field-free control of magnetic Josephson junctions and superconducting diode effects.

The tunneling resistance device 100 in FIG. 1A is also shown to include a flexible substrate 106 coupled to a surface of the insulating barrier layer 102. The flexible substrate 106 is configured to stretch and/or flex, and thereby transfer tensile strain along a crystal axis 107 of the insulating barrier layer 102. In an embodiment, the insulating barrier layer 102 is affixed or otherwise coupled to the flexible substrate 106 by a fastener 108. In an embodiment, the fastener 108 comprises one or more clamps. In an embodiment, the fastener 108 comprises gold. Since there tends to be a mismatch in Young's modulus between the 2D material and the flexible substrate 106, the strain transfer can be inefficient, resulting in slipping. This problem can be addressed by using evaporated metals, such as gold, to clamp the material to the substrate.

In an embodiment, the flexible substrate 106 is a gapless substrate 106. The gapless flexible substrate 106 comprises a single continuous strip and makes contact with the insulating barrier layer 102 along the entire length of the insulating barrier layer 102. A gapless substrate 106 as illustrated is in contrast to a substrate defining a gap which is spanned by the insulating barrier layer 102. The gapless substrate 106 is configured to stretch, and thereby transfer tensile strain along a crystal axis 107 of the insulating barrier layer 102. Advantageously, unlike substrates with gaps, which transfer strain unevenly, gapless polyimide substrates apply strain evenly along the entirety of the insulating barrier layer 102. In another embodiment, the flexible substrate 106 is a gapless polyimide substrate. In another embodiment, the flexible substrate 106 is a gapless polyamide substrate.

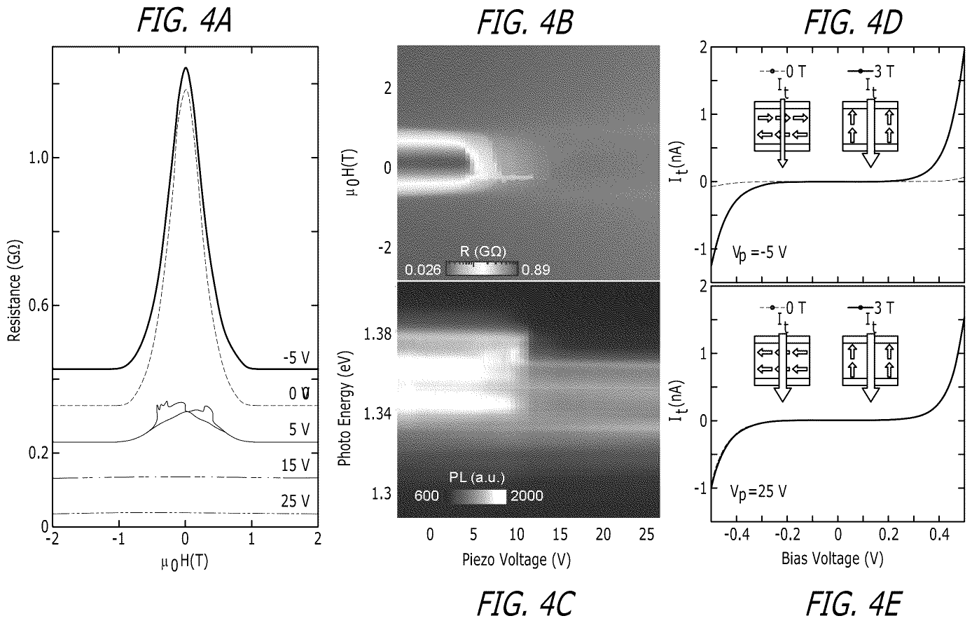

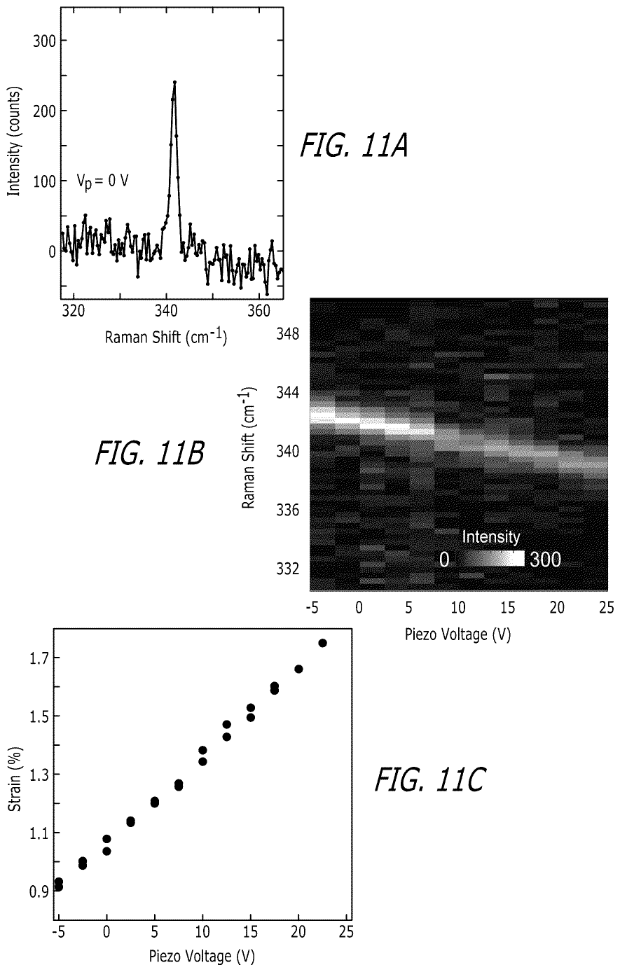

In an embodiment, the fastener 108 is formed around the insulating barrier layer 102 to substantially encapsulate or to entirely encapsulate the insulating barrier 102 and affix it to the flexible substrate 106. In an embodiment, the fastener 108 is a window clamping fastener 108, where a first side of the insulating barrier layer 102 is affixed to the flexible substrate 106, a second side of the insulating barrier layer 102 is substantially or entirely encapsulated by the fastener 108. In an embodiment, the fastener 108 defines an aperture 109 to surround one of the two or more electric contacts 104. This provides an aperture 109 window, where the aperture 109 window is configured to receive light from a light source for optical tests. In an embodiment, the optical tests comprise the photoluminescence (PL) experiments described further herein below in EXAMPLES 4-6 and FIGS. 4C, 9A-9C, and 10A-10D, the Raman experiments described in EXAMPLE 1 and FIGS. 11A-11B, or any other suitable optical test. In an embodiment, a second aperture (not shown) window is defined in the fastener 108 to surround a second of the two or more electrical contacts 104. The aperture 109 window provides flexibility to tune and characterize the behavior of the tunneling resistance device 100. In an embodiment, the fastener 108 fully surrounds the insulating barrier layer 102 such that no aperture 109 window is formed.

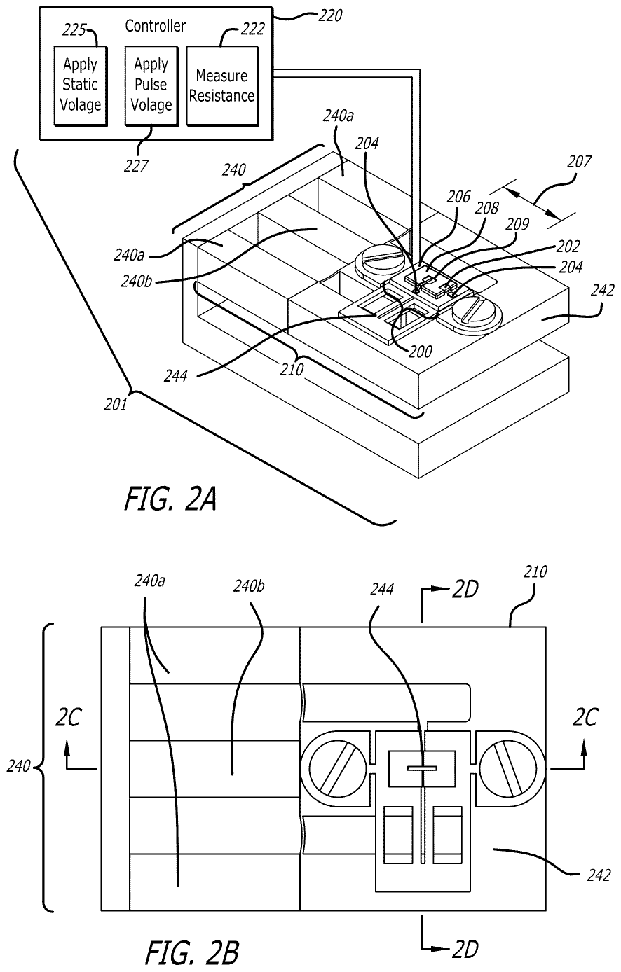

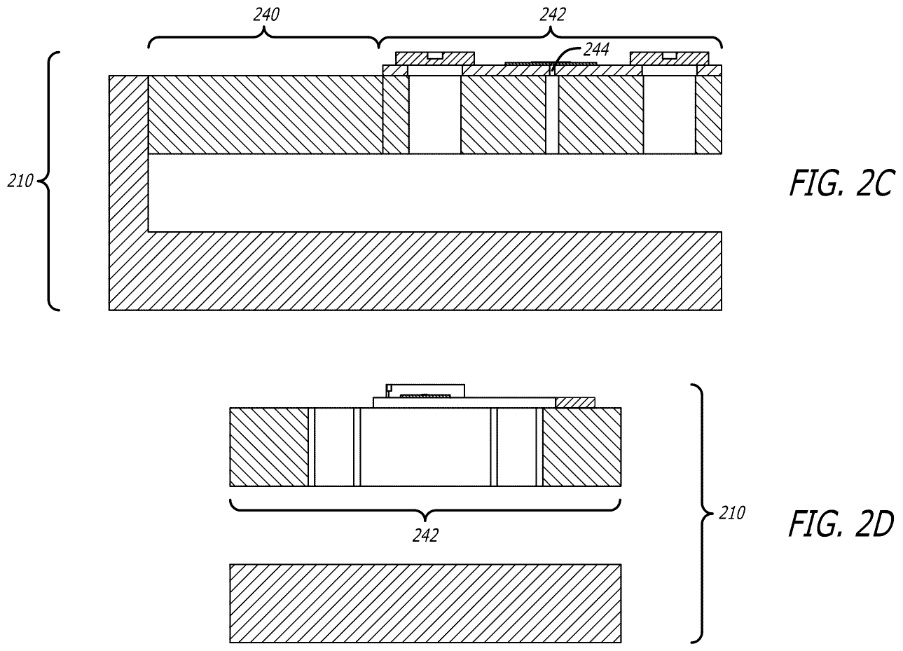

As discussed further herein with respect to FIGS. 2A-2D, in an embodiment, the flexible substrate 106 of the tunneling resistance device 100 is configured to couple with a piezoelectric strain cell, such as piezoelectric strain cell 210.

### Tunneling Resistance Systems

In an aspect, the present disclosure provides a system for inducing changes in TMR. In this regard, attention is directed to FIGS. 2A-2D in which a tunneling resistance system is illustrated.

FIG. 2A is a perspective view of a system 201 in accord with an aspect of the present disclosure. The illustration depicts a piezoelectric strain cell 210 physically coupled with a tunneling resistance device 200 and operatively coupled to a controller 220, in accordance with an embodiment of the present disclosure. FIG. 2B is a plan view of the piezoelectric strain cell 210. FIG. 2C is a cross-sectional side view of the piezoelectric strain cell 210 taken along a line at substantially the midpoint of the width of the device 200 of FIG. 2B. FIG. 2D is a cross-sectional side view of the tunneling resistance device 200 taken along a line at substantially the midpoint of the length of the device 200 of FIG. 2B.

As shown, the tunneling resistance device 200 comprises an insulating barrier layer 202 comprising a van der Waals semiconductor; two or more electrical contacts 204 in electrically conductive communication with opposing sides of the insulating barrier layer 202; and a flexible substrate 206 coupled to a surface of the insulating barrier layer 202. The flexible substrate 206 is configured to stretch and/or flex, and thereby transfer tensile strain along a crystal axis 207 of the insulating barrier layer 202. In the illustrated embodiment, the insulating barrier layer 202 is affixed to the flexible substrate 206 by a fastener 208. In an embodiment, the fastener 208 defines an aperture 209 to surround one of the two or more electric contacts 204. In an embodiment, the tunneling resistance device 200 is an example of device 100 discussed further herein with respect to FIGS. 1A-1D.

The system 201 depicted in FIG. 2A also comprises the piezoelectric strain cell 210. The piezoelectric strain cell 210 is shown coupled with a flexible substrate 206 of a tunneling resistance device 200. In an embodiment, an insulating barrier layer 202 is configured to receive a tensile strain on actuation of the piezoelectric strain cell 210 as transferred through the flexible substrate 206. In an embodiment, the flexible substrate 206 is affixed to a sample plate which is configured to be attached and detached from the piezoelectric strain cell 210. In an embodiment, the piezoelectric strain cell 210 comprises three piezo-stacks 240, which are glued or otherwise affixed to a W-shaped flexure element 242. When a positive voltage is applied, the outside stacks 240a expand while the inner stack 240b contracts, causing a gap 244 to open and tensile strain to be applied to the material which is glued across the gap 244. A benefit of this symmetric configuration is that the thermal expansion from each piezo stack 240 cancels out, resulting in negligible thermal strain from the piezo stacks 240 themselves. Since strain is proportional to the fractional change in length of the material, it is possible to achieve very large strain by making the gap 244 very small.

In an embodiment, a static voltage is applied to the piezoelectric strain cell 210, thereby inducing a tensile strain on the flexible substrate 206, and accordingly to the insulating barrier layer 202. In an embodiment, the static voltage is sufficient to induce switching of at least one interlayer coupling between individual monolayers of the van der Waals semiconductor from AFM to FM without using a magnetic field. In an embodiment, the static voltage is sufficient to induce switching of at least two interlayer couplings between individual monolayers of the van der Waals semiconductor from AFM to FM without using a magnetic field. In an embodiment, the static voltage is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, and at least twelve interlayer couplings between individual monolayers of the van der Waals semiconductor from AFM to FM without using a magnetic field. In another alternative embodiment, any of the preceding interlayer couplings are switched in the presence of a magnetic field.

In an embodiment, a static voltage applied to the piezoelectric strain cell 210 is reduced, thereby reducing a tensile strain on the flexible substrate 206, and accordingly to the insulating barrier layer 202. In an embodiment, the static voltage reduction is sufficient to induce switching of at least one interlayer coupling between individual monolayers of the van der Waals semiconductor from FM to AFM without using a magnetic field. In an embodiment, the static voltage reduction is sufficient to induce switching of at least two interlayer couplings between individual monolayers of the van der Waals semiconductor from FM to AFM without using a magnetic field. In an embodiment, the static voltage reduction is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from FM to AFM without using a magnetic field. In another alternative embodiment, any of the preceding interlayer couplings are switched in the presence of a magnetic field.

In an embodiment, strain switching between layered A-type AFM and FM states produces exceptionally large TMR in straintronic MTJ heterostructures which incorporate as the insulating barrier layer 202 a van der Waals semiconducting material, such as layered A-type van der Waals antiferromagnet, such as CrSBr, CrI₃, and CrPS₄. The application of strain to a tunneling resistance device 200 in accordance with an embodiment of the present disclosure provides an energy-efficient operating principle in comparison to standard MTJ operating methods, as strain requires little to no current to switch the magnetic state. In an embodiment, the air stability and relatively high ordering temperature provide further advantages in using CrSBr in comparison to the other 2D A-type AFMs.

In an embodiment, a static voltage is applied to the piezoelectric strain cell 210, where the static voltage is a stochastic switching voltage, thereby inducing a tensile strain on the flexible substrate 206, and accordingly to the insulating barrier layer 202. In an embodiment, the stochastic switching voltage is sufficient to induce stochastic switching of at least one interlayer coupling between individual monolayers of the van der Waals semiconductor from AFM to FM without using a magnetic field. In an embodiment, the stochastic switching voltage is finely and continuously tuned, thereby finely and continuously tuning the energy barrier between AFM and FM interlayer couplings. In an embodiment, a device in such a configuration operates as a p-bit type domain. In an embodiment, as described further herein below in EXAMPLE 9, a response function is calculated, where a response function value of 0 or 1 indicates a stable magnetic domain, while a value of 0.5 indicates equal fluctuations between the two stable states. The ability to finely tune the response function should enable both random number generation at p=0.5 and a biased Bernoulli sequence at higher or lower values, which can be useful for applications dealing with Ising and probabilistic computing. In an embodiment, the applied bias voltage is used to tune the response function by increasing or decreasing the switching rate, potentially providing fine control near the edges of the sigmoidal curve, while also enabling interaction between multiple p-bits. In principle, the two independent control parameters (strain and bias voltage) offers independent tuning of the effective temperature and energy landscape of the p-bit, thereby allowing direct stochastic annealing of a p-bit system. Such a scheme significantly reduces the circuit complexity used to realize a large-scale analog p-bit annealer.

Referring still to FIGS. 2A-2D, the system 201 is depicted to comprise a controller 220. The controller 220 is a functional element that choreographs and controls the operation of the other functional elements. In one embodiment, controller 220 is implemented with hardware logic (e.g., application specific integrated circuit, field programmable gate array, etc.). In yet another embodiment, controller 220 may be implemented as a general-purpose microcontroller 220 that executes software or firmware instructions stored in memory (e.g., non-volatile memory, etc.). Yet alternatively, controller 220 may be implemented in a combination of hardware and software and further may be centralized or distributed across multiple components.

As shown, the controller 220 is operatively coupled to the piezoelectric strain cell 210. As discussed further herein with respect to the piezoelectric strain cell 210, in an embodiment, the signal sent by the controller 220 is suitable to adjust the voltage applied to the piezoelectric strain cell 210, thereby changing the tensile strain applied to the tunneling resistance device 200 disposed thereon. In an embodiment, the controller 220 includes logic that, when executed by the controller 220, causes the system 201 to perform operations in accordance with an embodiment of the present system 201. In an embodiment, the operations include one or more steps of the methods of the present disclosure discussed further herein.

In an embodiment, the operations including inducing application of a static voltage 225 to the piezoelectric strain cell 210, thereby inducing a tensile strain on the flexible substrate 206, and accordingly to the insulating barrier layer 202. In an embodiment, the static voltage is sufficient to induce switching of at least one interlayer coupling between individual monolayers of the van der Waals semiconductor from AFM to FM without using a magnetic field. In an embodiment, the static voltage is sufficient to induce switching of at least two interlayer couplings between individual monolayers of the van der Waals semiconductor from AFM to FM without using a magnetic field. In an embodiment, the static voltage is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from AFM to FM without using a magnetic field. In another alternative embodiment, any of the preceding interlayer couplings are switched in the presence of a magnetic field.

In an embodiment, a static voltage applied to the piezoelectric strain cell 210 is reduced, thereby reducing a tensile strain on the flexible substrate 206, and accordingly to the insulating barrier layer 202. In an embodiment, the static voltage reduction is sufficient to induce switching of at least one interlayer coupling between individual monolayers of the van der Waals semiconductor from FM to AFM without using a magnetic field. In an embodiment, the static voltage reduction is sufficient to induce switching of at least two interlayer couplings between individual monolayers of the van der Waals semiconductor from FM to AFM without using a magnetic field. In an embodiment, the static voltage reduction is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from FM to AFM without using a magnetic field. In another alternative embodiment, any of the preceding interlayer couplings are switched in the presence of a magnetic field.

In an embodiment, strain switching between layered A-type AFM and FM states produces exceptionally large TMR in straintronic MTJ heterostructures which incorporate as the insulating barrier layer 202 a van der Waals semiconducting material, such as layered A-type van der Waals antiferromagnet, such as CrSBr, CrI₃, and CrPS₄. The application of strain to a tunneling resistance device 200 in accordance with an embodiment of the present disclosure provides an energy-efficient operating principle in comparison to standard MTJ operating methods, as strain requires little to no current to switch the magnetic state. In an embodiment, the air stability and relatively high ordering temperature provide further advantages in using CrSBr in comparison to the other 2D A-type AFMs.

In an embodiment the static voltage applied to the piezoelectric strain cell 210, is a stochastic switching voltage, thereby inducing a tensile strain on the flexible substrate 206, and accordingly to the insulating barrier layer 202. In an embodiment, the stochastic switching voltage is sufficient to induce stochastic switching of at least one interlayer coupling between individual monolayers of the van der Waals semiconductor from AFM to FM without using a magnetic field. In an embodiment, the stochastic switching voltage is finely and, for example, continuously tuned, thereby finely and continuously tuning the energy barrier between AFM and FM interlayer couplings. In an embodiment, the system 201 in such a configuration operates as a p-bit type domain. In an embodiment, described further herein below in EXAMPLE 9, a response function is calculated, where a response function value of 0 or 1 indicates a stable magnetic domain, while a value of 0.5 indicates equal fluctuations between the two stable states. The ability to finely tune the response function should enable both random number generation at p=0.5 and a biased Bernoulli sequence at higher or lower values, which can be useful for applications dealing with Ising and probabilistic computing. In an embodiment, the applied bias voltage is also used to tune the response function by increasing or decreasing the switching rate, potentially providing fine control near the edges of the sigmoidal curve, while also enabling interaction between multiple p-bits. In principle, the two independent control parameters (strain and bias voltage) also offer independent tuning of the effective temperature and energy landscape of the p-bit, thereby allowing direct stochastic annealing of a p-bit system. Such a scheme significantly reduces the circuit complexity used to realize a large-scale analog p-bit annealer.

In an embodiment, the response function is between 0 and 0.1, or between 0.1 and 0.2, or between 0.2 and 0.3, or between 0.3 and about 0.4, or between about 0.4 and about 0.5, or between about 0.5 and about 0.6, or between about 0.6 and about 0.7, or between about 0.7 and about 0.8, or between about 0.8 and about 0.9, or between about 0.9 and about 1.0, as well as any combination of ranges provided herein above.

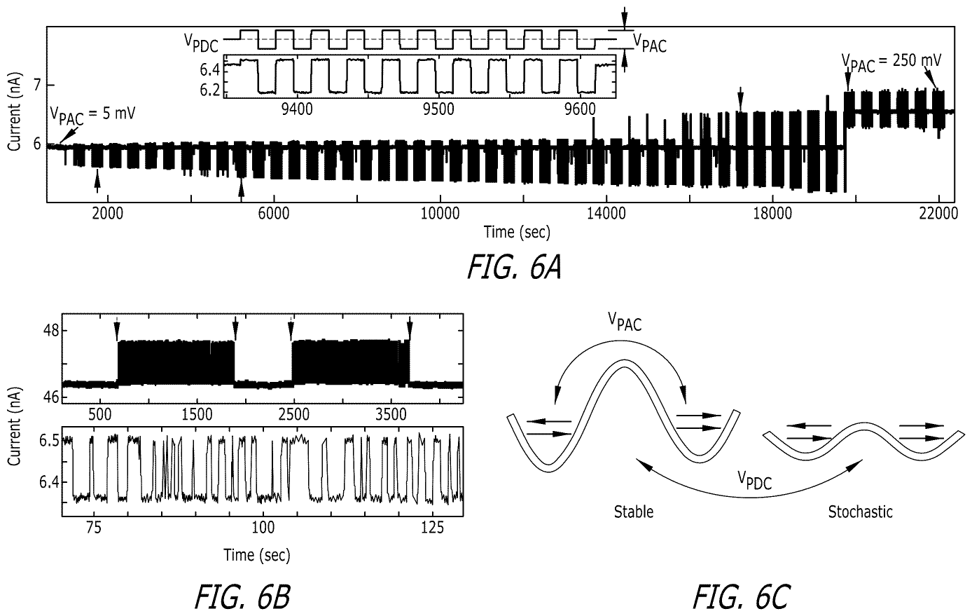

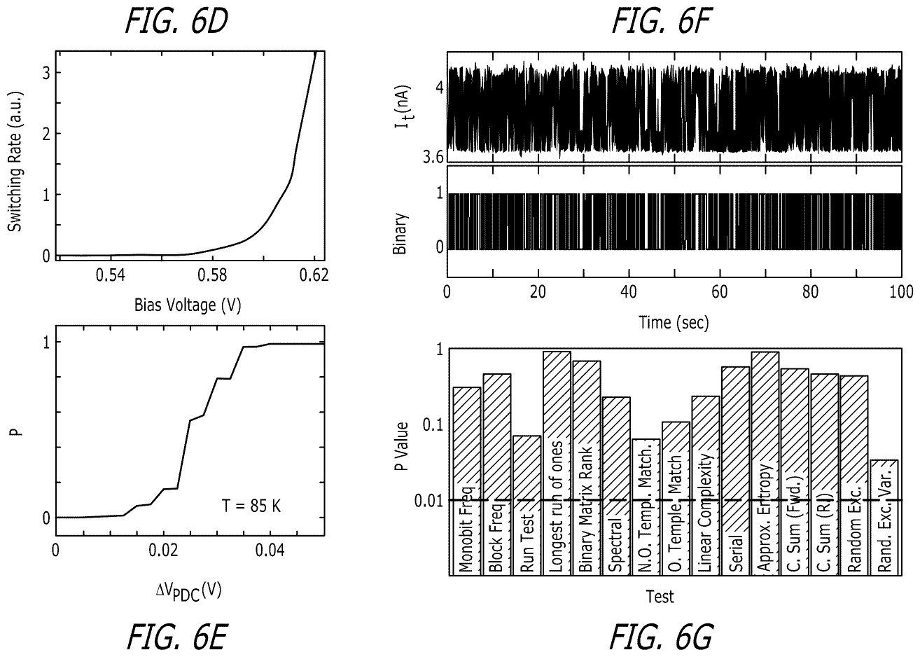

In an embodiment, the controller 220 is operatively coupled to the piezoelectric strain cell 210 includes logic that, when executed by the controller 220, causes the system 201 to apply a switchable pulse voltage 227 to the piezoelectric strain cell 210 with a potential sufficient to stably switch at least one additional interlayer coupling between individual monolayers of the van der Waals semiconductor from AFM to FM. In an embodiment, this voltage is switched on and off, thereby enabling in-situ control of the tunneling resistance of the tunneling resistance device 200. In an embodiment, as depicted in FIG. 6 and discussed further herein below, the controller 220 applies a static voltage 225, thereby inducing a tensile strain on the flexible substrate 206, and accordingly to the insulating barrier layer 202, and subsequently the controller 220 applies a pulse voltage 227, where the pulse voltage 227 is sufficient to induce switching of at least one interlayer coupling between individual monolayers of the van der Waals semiconductor from AFM to FM without using a magnetic field. In an embodiment, the static voltage is sufficient to induce switching of at least two interlayer couplings between individual monolayers of the van der Waals semiconductor from AFM to FM without using a magnetic field. In an embodiment, the static voltage is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from AFM to FM without using a magnetic field. In another alternative embodiment, any of the preceding interlayer couplings are switched in the presence of a magnetic field.

In an embodiment, the pulse voltage is in the range of greater than 0 mV to about 5 mV. In an embodiment, the pulse voltage is in the range of greater than 0 mV to about 25 mV. In an embodiment, the pulse voltage is in the range of about 25 mV to about 100 mV. In an embodiment, the pulse voltage is in the range of about 100 mV to about 250 mV. In an embodiment, the pulse voltage is in the range of about 25 mV to about 250 mV. Without being bound by theory, a narrow pulse voltage range has the advantage of providing a controlled switching of a particular number of interlayer couplings, while a broad pulse voltage range has the advantage of enabling in-situ tuning of the desired number of interlayer couplings to switch. As seen in FIG. 6A, in an embodiment, larger values of the pulse voltage induce additional switches in interlayer couplings in a step-wise manner.

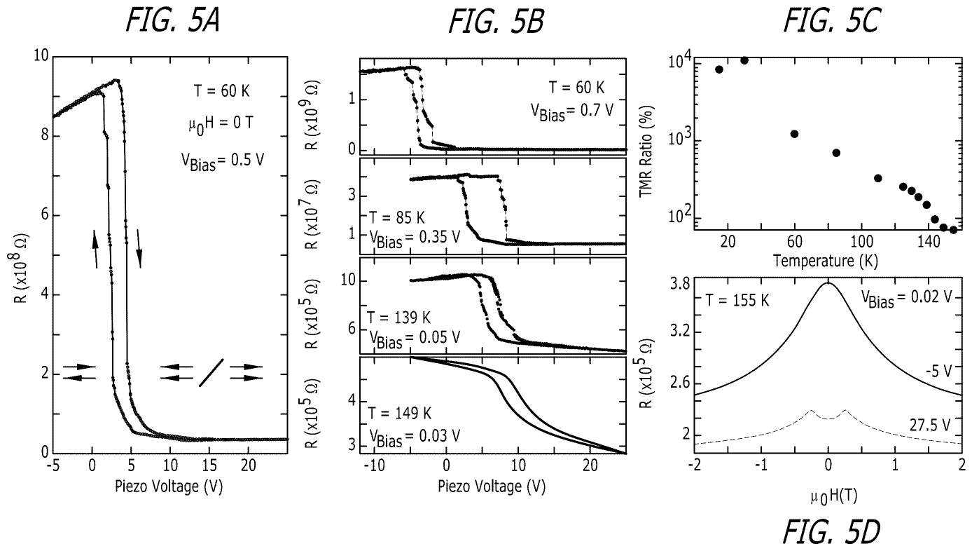

The controller 220 of the system 201 depicted in FIG. 2A is also configured to perform the operations of measuring an electrical resistance 222 through the insulating barrier layer 202. In an embodiment, the electrical resistance through the insulating barrier layer 202 is measured when the interlayer coupling between monolayers of the insulating barrier layer 202 are AFM. In an embodiment, the electrical resistance through the insulating barrier layer 202 is measured when at least one interlayer coupling between monolayers of the insulating barrier 202 layer is FM. In an embodiment, a TMR ratio is calculated by comparing the resistance measured when the interlayer coupling between monolayers of the insulating barrier layer 202 are AFM and when one or more interlayer couplings between monolayers of the insulating barrier layer 202 have switched to be FM. In an embodiment, the TMR ratio is calculated with the equation TMR (%)=(R_{antiferromagnetic}−R_{ferromagnetic})/R_{ferromagnetic}. As discussed further herein below with respect to EXAMPLE 7 and FIGS. 5A-5C, in an embodiment the TMR remains above 100% at temperatures up to about 140 K, and exceeds 10,000% at 30 K. The sharpness of the transitions leading to a particular TMR ratio is also temperature dependent, as shown in FIG. 5B, where lower temperatures have the advantage of sharp AFM to FM phase transitions, whereas higher temperatures have the advantage of allowing for the tunneling resistance device 200 to function at higher temperatures and corresponding cost savings. In an embodiment, the TMR ratio is greater than 100%. In an embodiment, the TMR ratio is greater than 300%. In an embodiment, the TMR ratio is greater than 1000%. In an embodiment, the TMR ratio is greater than 3100%. In an embodiment, the TMR ratio is greater than 10,000%.

In an embodiment, the TMR ratio of a device 200 varies as the operating temperature of the device 200 varies. In an embodiment, the temperature is maintained in the range of greater than 0 K and about 30 K, in the range of greater than 0 K and about 60 K, in the range of greater than 0 K and about 100 K, in the range of greater than 0 K and about the Neel temperature of the van der Waals semiconductor, in the range of about 30 K and about 60 K, in the range of about 30 K and about 100 K, and in the range of about 30 K and about the Neel temperature of the van der Waals semiconductor.

### Tunneling Resistance Methods

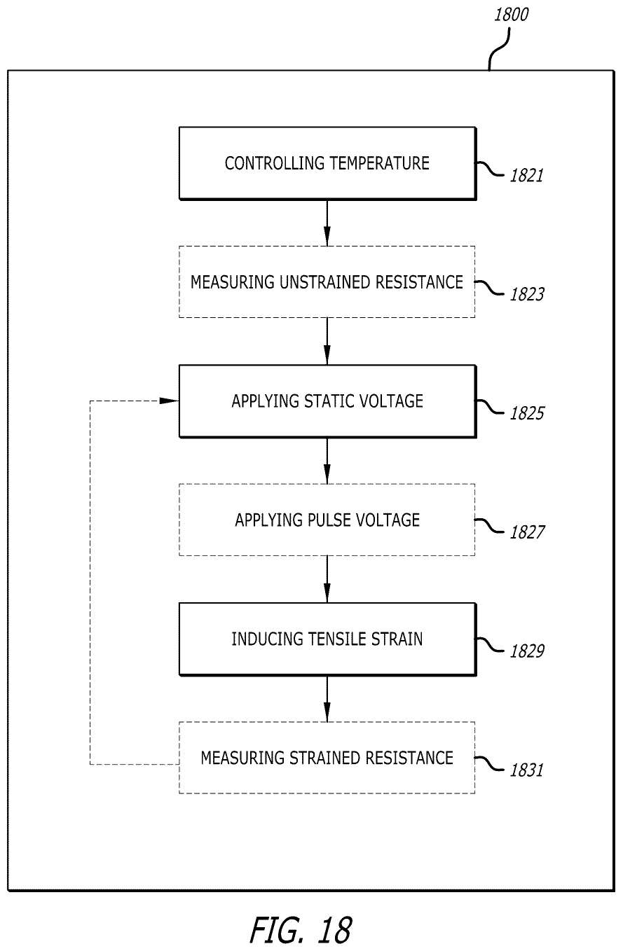

In an aspect, the present disclosure provides a method for switching an interlayer magnetic coupling from antiferromagnet to FM. In this regard, attention is directed to FIG. 18 in which a method for operating a tunneling resistance device is illustrated. FIG. 18 illustrates an example of method 1800, which may be used to operate a tunneling resistance device, such as tunneling resistance devices 100, 200, and 300.

In an aspect, method 1800 is operated on a tunneling resistance assembly (not pictured), the tunneling resistance assembly comprises a tunneling resistance device comprising an insulating barrier layer comprising a van der Waals semiconductor, two or more electrical contacts in electrically conductive communication with opposing sides of the insulating barrier layer, and a flexible substrate coupled to a surface of the insulating barrier layer; and a piezoelectric strain cell, wherein the tunneling resistance device and the flexible substrate are coupled to the piezoelectric strain cell and configured to receive a tensile strain from the piezoelectric strain cell. In this regard, in an embodiment, the tunneling resistance device is an example of device 200 discussed further herein with respect to FIGS. 2A-2D, and the piezoelectric strain cell coupled with the flexible substrate, in an embodiment, is an example of piezoelectric strain cell 210 discussed further herein with respect to FIGS. 2A-2D. In an embodiment, method 1800 is operated on tunneling resistance device 200.

In an embodiment, the method 1800 begins with a process block 1821 including controlling a temperature 1821 of an environment of or surrounding the tunneling resistance device. In an embodiment, this temperature is a switching temperature. In an embodiment, the temperature is in the range of greater than 0 K and about 30 K, in the range of greater than 0 K and about 60 K, in the range of greater than 0 K and about 100 K, in the range of greater than 0 K and about the Neel temperature of the van der Waals semiconductor, in the range of about 30 K and about 60 K, in the range of about 30 K and about 100 K, and in the range of about 30 K and about the Neel temperature of the van der Waals semiconductor, or greater.

In an embodiment, method 1800 includes optional process block 1823, which includes measuring an unstrained resistance through the tunneling resistance device.

Method 1800 is also shown to include process block 1825, which includes applying static voltage 1825 to the piezoelectric device. In an embodiment, the method 1800 also includes the optional process block of applying pulse voltage 1827 to the piezoelectric strain cell. In an embodiment, this voltage is switched on and off, thereby enabling in-situ control of the voltage applied to the tunneling resistance device.

In an embodiment, process block 1825 is followed by process block 1829, which includes inducing tensile strain 1829 in the insulating barrier layer. In an embodiment, applying static voltage and, optionally, applying a pulse voltage to the piezoelectric device induces tensile strain on the tunneling resistance device. When the static voltage is sufficiently large, the tensile strain is capable of inducing switching of at least one interlayer coupling between individual monolayers of the van der Waals semiconductor from AFM to FM.

In an embodiment, the static voltage is sufficient to induce switching of at least two interlayer couplings between individual monolayers of the van der Waals semiconductor from AFM to FM without using a magnetic field. In an embodiment, the static voltage is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from AFM to FM without using a magnetic field. In another alternative embodiment, any of the preceding interlayer couplings are switched in the presence of a magnetic field.

In an embodiment, strain switching between layered A-type AFM and FM states produces exceptionally large TMR in straintronic MTJ heterostructures which incorporate as the insulating barrier layer a van der Waals semiconducting material, such as layered A-type van der Waals antiferromagnet, such as CrSBr, CrI₃, and CrPS₄. The application of strain to a tunneling resistance device in accordance with an embodiment of the present disclosure provides an energy-efficient operating principle in comparison to standard MTJ operating methods, as strain requires little to no current to switch the magnetic state. In an embodiment, the air stability and relatively high ordering temperature provide further advantages in using CrSBr in comparison to the other 2D A-type AFMs.

In an embodiment, depicted, for example, in FIG. 6 and discussed further herein below, the application of a static voltage and subsequently applying a pulse voltage induces a baseline tensile strain in the tunneling resistance device, followed by a pulsing strain. In an embodiment, the pulse voltage is chosen to be sufficient to induce switching of at least one interlayer coupling between individual monolayers of the van der Waals semiconductor from AFM to FM without using a magnetic field. In an embodiment, the pulse voltage is sufficient to induce switching of at least two interlayer couplings between individual monolayers of the van der Waals semiconductor from AFM to FM without using a magnetic field. In an embodiment, the pulse voltage is sufficient to induce switching of at least three interlayer couplings, at least four interlayer couplings, at least five interlayer couplings, at least six interlayer couplings, at least seven interlayer couplings, at least eight interlayer couplings, at least nine interlayer couplings, at least ten interlayer couplings, at least eleven interlayer couplings, or at least twelve interlayer couplings between individual monolayers of the van der Waals semiconductor from AFM to FM without using a magnetic field. In another alternative embodiment, any of the preceding interlayer couplings are switched in the presence of a magnetic field.

In an embodiment, the pulse voltage is in the range of greater than 0 mV to about 5 mV. In an embodiment, the pulse voltage is in the range of greater than 0 mV to about 25 mV. In an embodiment, the pulse voltage is in the range of about 25 mV to about 100 mV. In an embodiment, the pulse voltage is in the range of about 100 mV to about 250 mV. In an embodiment, the pulse voltage is in the range of about 25 mV to about 250 mV.

The method 1800 is shown to further include optional process block 1831, which includes measuring a strained resistance in the tunneling resistance device. When combined with optional process block measuring unstrained resistance 1823, this allows the resistance to be measured both when the interlayer coupling between monolayers of the insulating barrier layer are AFM and the resistance measured when the interlayer coupling between monolayers of the insulating barrier layer are FM. With these measurements, a TMR ratio is calculated. In an embodiment, the TMR ratio is calculated with the equation TMR (%)=(R_{antiferromagnetic}−R_{ferromagnetic})/R_{ferromagnetic}. In an embodiment, the TMR ratio is greater than 100%. In an embodiment, the TMR ratio is greater than 300%. In an embodiment, the TMR ratio is greater than 1000%. In an embodiment, the TMR ratio is greater than 3100%. In an embodiment, the TMR ratio is greater than 10,000%.

In an embodiment, the TMR ratio of a device varies as the operating temperature of the device varies. In an embodiment, the temperature is maintained in the range of greater than 0 K and about 30 K, in the range of greater than 0 K and about 60 K, in the range of greater than 0 K and about 100 K, in the range of greater than 0 K and about the Neel temperature of the van der Waals semiconductor, in the range of about 30 K and about 60 K, in the range of about 30 K and about 100 K, and in the range of about 30 K and about the Neel temperature of the van der Waals semiconductor, or greater.

As a final step, method 1800 includes an optional loop wherein, following measuring strained resistance 1831, the step applying static voltage 1825 is repeated as discussed in any of the embodiments disclosed herein above.

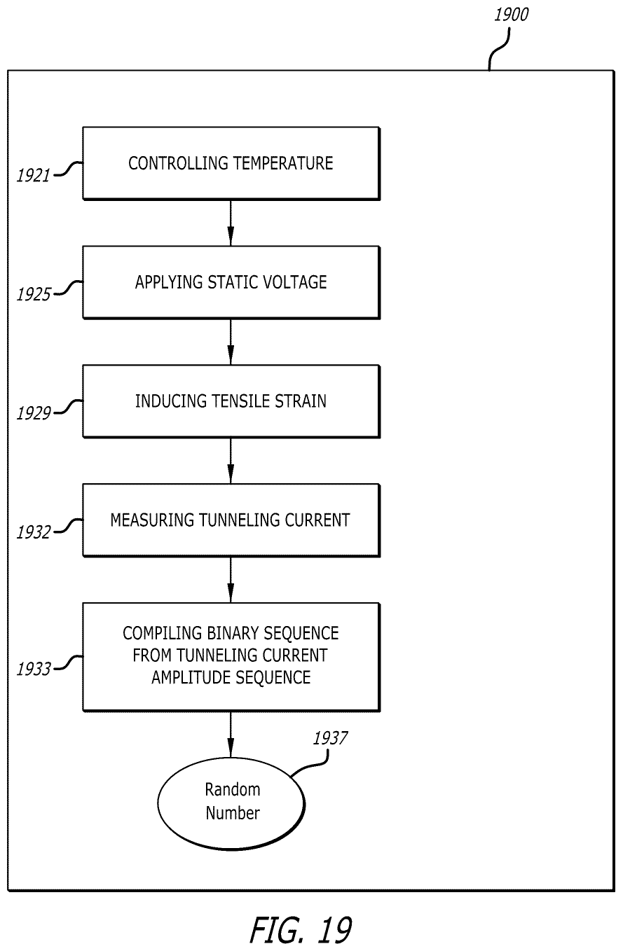

FIG. 19 depicts a block diagram for method 1900 which allows for a tunneling resistance device in accordance with any of the embodiments discussed further herein above to operate as a random number generator in accordance with an embodiment of the present disclosure.

In an aspect, method 1900 is operated on a tunneling resistance assembly (not pictured), the tunneling resistance assembly comprising: a tunneling resistance device comprising an insulating barrier layer comprising a van der Waals semiconductor, two or more electrical contacts in electrically conductive communication with opposing sides of the insulating barrier layer, and a flexible substrate coupled to a surface of the insulating barrier layer; and a piezoelectric strain cell, wherein the tunneling resistance device and the flexible substrate are coupled to the piezoelectric strain cell and configured to receive a tensile strain from the piezoelectric strain cell. In this regard, in an embodiment, the tunneling resistance device is an example of device 200 discussed further herein with respect to FIGS. 2A-2D, and the piezoelectric strain cell coupled with the flexible substrate, in an embodiment, is an example of piezoelectric strain cell 210 discussed further herein with respect to FIGS. 2A-2D. In an embodiment, method 1900 is operated on the tunneling resistance device 200.

As shown, method 1900 begins with a process block 1921, which includes controlling the temperature 1921 of the environment in which the tunneling resistance device is maintained. In an embodiment, this temperature is a switching temperature, and is in the range of greater than 0 K and about 30 K, in the range of greater than 0 K and about 60 K, in the range of greater than 0 K and about 100 K, in the range of greater than O K and about the Neel temperature of the van der Waals semiconductor, in the range of about 30 K and about 60 K, in the range of about 30 K and about 100 K, and in the range of about 30 K and about the Neel temperature of the van der Waals semiconductor, or greater.

In an embodiment, process block 1921 is followed by process block 1925, which includes applying static voltage 1925 to the piezoelectric device.

In the illustrated embodiment, method 1900 next includes a process block 1929, which includes inducing tensile strain 1929 in the insulating barrier layer. In an embodiment, implementing process block applying static voltage 1929 to the piezoelectric device induces tensile strain on the tunneling resistance device. When the static voltage is sufficiently large, the resulting tensile strain is capable of inducing switching of at least one interlayer coupling between individual monolayers of the van der Waals semiconductor from AFM to FM.

In an embodiment, the static voltage is a stochastic domain switching voltage, wherein the stochastic domain switching voltage is sufficient to enable a stochastic switching of at least one interlayer coupling between individual monolayers of the van der Waals semiconductor from AFM to FM. In this manner, the stochastic switching voltage is finely and, for example, continuously tuned, thereby finely and continuously tuning the energy barrier between AFM and FM interlayer couplings. In an embodiment in accordance with an aspect of this disclosure, a device in such a configuration operates as a p-bit type domain. In an embodiment, described further herein below in EXAMPLE 9, a response function is calculated, where a response function value of 0 or 1 indicates a stable magnetic domain, while a value of 0.5 indicates equal fluctuations between the two stable states. The ability to finely tune the response function should enable both random number generation at p=0.5 and a biased Bernoulli sequence at higher or lower values, which can be useful for applications dealing with Ising and probabilistic computing. In an embodiment, the applied bias voltage is also used to tune the response function by increasing or decreasing the switching rate, potentially providing fine control near the edges of the sigmoidal curve, while also enabling interaction between multiple p-bits. In principle, the two independent control parameters (strain and bias voltage) offers independent tuning of the effective temperature and energy landscape of the p-bit, thereby allowing direct stochastic annealing of a p-bit system. Such a scheme significantly reduces the circuit complexity used to realize a large-scale analog p-bit annealer.

In an embodiment, the response function is between 0 and 0.1, or between 0.1 and 0.2, or between 0.2 and 0.3, or between 0.3 and about 0.4, or between about 0.4 and about 0.5, or between about 0.5 and about 0.6, or between about 0.6 and about 0.7, or between about 0.7 and about 0.8, or between about 0.8 and about 0.9, or between about 0.9 and about 1.0, as well as any combination of ranges provided herein above.

As shown, the method 1900 further includes a process block 1932, which includes measuring a tunneling current 1932 through the tunneling resistance device. The current amplitude in a device in accordance with the methods employed will switch stochastically between a high and a low state. In the illustrated embodiment, the method 1900 includes the subsequent process block 1933, which includes compiling a binary sequence from the tunneling current amplitude sequence. In the stochastic switching state, the binary sequence represents a random number 1937.

In an embodiment, the stochastic domain switching voltage is adjusted during operation. In so doing, the response function changes, inducing a change in the ratio of high versus low tunneling currents states measured. In this way, the tunneling resistance device operates as an in-situ probabilistic bit.

The order in which some or all of the process blocks appear in each process should not be deemed limiting. Rather, one of ordinary skill in the art having the benefit of the present disclosure will understand that some of the process blocks may be executed in a variety of orders not illustrated, or even in parallel.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

A tangible machine-readable storage medium includes any mechanism that provides (i.e., stores) information in a non-transitory form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated embodiments of the disclosure, including what is described in the Abstract, is not intended to be exhaustive or to limit the disclosure to the precise forms disclosed. While specific embodiments of, and examples for, the disclosure are described herein for illustrative purposes, various modifications are possible within the scope of the disclosure, as those skilled in the relevant art will recognize.

These modifications can be made to the disclosure in light of the above detailed description. The terms used in the following claims should not be construed to limit the disclosure to the specific embodiments disclosed in the specification. Rather, the scope of the disclosure is to be determined entirely by the following claims, which are to be construed in accordance with established doctrines of claim interpretation.

### EXEMPLARY ASPECTS

The following Examples are included for the purpose of illustrating, not limiting, the disclosed embodiments.

### Example 1: Device Fabrication and Strain Application

The present example relates to the fabrication of tunneling resistance devices and the application of strain thereto. Here, the coupling of the anisotropic Wannier-type excitons to the layered AFM structure in thin CrSBr is explored. The A-type AFM structure comprises FM ordered monolayer planes that are AFM coupled along the stacking direction, forming intrinsic spin filters which generate exceptionally high TMR. Applying an external magnetic field to A-type AFMs in the weak exchange limit switches the magnetic state from the fully AFM, high resistance configuration to intermediate states with layer-dependent interlayer coupling, and then finally to a fully aligned, low resistance FM state (see FIG. 3A, discussed further herein below). In comparison to the previous works on conventional van der Waals MTJs which require the continuous application of magnetic field to control the magnetic states, strain provides an exceptionally energy-efficient operating mechanism as it requires essentially no current. Moreover, the fine, continuous, and reversible tuning of the interlayer exchange enables unprecedented control of the layer-dependent magnetic structure. However, the physics of magnetic domain formation during the first-order magnetic phase transition has yet to be explored, and there have so far been experimental challenges in applying sufficient strain to van der Waals devices at cryogenic temperatures to switch the CrSBr from AFM to FM.

The exciton PL is shown to exhibit distinct energy shifts when the spins are aligned by an external magnetic field. As a result, PL provides a probe of the in-plane AFM order, which is challenging to study using more conventional means due to the vanishing net magnetic moment and reduced dimensionality of the 2D samples. Using the exciton as a sensor, the effects of uniaxial strain applied along the a crystal axis on the magnetic ordering are studied. It is shown that strain reduces the saturating magnetic field and eventually culminates in a reversible strain-induced AFM to FM magnetic phase transition at high strains. The phase transition occurs due to a changing bond geometry which continuously tunes the interlayer magnetic exchange, which changes sign at the critical strain. Strained CrSBr thus offers an exciting platform for manipulating and probing nanoscale magnetism due to the interplay of spin, charge, and lattice degrees of freedom.

To prepare the strain substrate, transparent 20 μm thick polyimide is cut into strips and epoxied them onto 2D flexure sample plates produced by Razorbill Instruments, Ltd. using LOCTITE® STYCAST™ 2850 FT epoxy. The distance between the edge of the epoxy on either side of the gap was less than 200 μm to enable large strains.

Bulk CrSBr is exfoliated to the monolayer limit, as shown in FIG. 7A, yielding large rectangular flakes which are air-stable in bilayer and thicker samples. The orthorhombic crystal structure enables easy identification of the crystal axes 707, with the short and long axes corresponding to the b and a axes, respectively. When monolayer CrSBr is cooled, in-plane FM ordering with triaxial magnetic anisotropy onsets below a relatively high Curie temperature of T_{c}˜146 K. The magnetic easy, intermediate, and hard axes are aligned along the b, a, and c crystal axes 707, respectively. When the monolayers 703a are stacked, i.e. in bilayer and thicker flakes to form an insulating barrier layer 702, the weak AFM interlayer coupling 712 produces an A-type layered AFM structure, as shown schematically in FIG. 7B, below a relatively high Neel temperature of T_{N}˜132 K. This A-type structure is common to many 2D magnetic materials and is ideal for use in spintronic devices such as MTJs since the layer-dependent magnetization forms intrinsic, atomically sharp spin filters. The spins in FIG. 7B are oriented along the b axis 707, which is the short axis in FIG. 7A. For strain experiments, the strain is applied along the long a axis 707. In addition to the high ordering temperatures and air stability, CrSBr distinguishes itself from the other 2D magnets due to its semiconducting properties which have been established by scanning tunneling microscopy and electrical transport experiments.

Bulk CrSBr crystals were grown by the same method detailed previously by Schie et al. (Scheie, A. et al. “Spin Waves and Magnetic Exchange Hamiltonian in CrSBr”. Advanced Science 9, 2022: 2202467). The bulk CrSBr and graphite crystals were exfoliated onto PDMS substrates using standard methods and thin (˜10 nm) flakes were identified by optical contrast. The MTJs were then assembled through a dry transfer technique with a stamp consisting of a polypropylene carbonate (PPC) film spin coated onto a polydimethylsiloxane (PDMS) cylinder. The flakes were picked up in the following order before being deposited onto the polyimide substrate: top graphite, CrSBr, bottom graphite. The long axis of the CrSBr flake was aligned with the strain axis.

After depositing the MTJ heterostructure, the window clamping pattern and electrical contacts to the two graphite contacts were fabricated using standard electron beam lithography techniques with a metal thickness of 7 and 70 nm Cr and Au, respectively. Then, the sample plate was screwed into the symmetric three-piezo strain cell depicted in FIG. 2A.

To calibrate the strain during the experiment, we used the Raman shift rate of the mode near ˜346 cm⁻¹. There was a rather large built-in strain of ˜0.9 %, which is consistent with the small saturating field in the out-of-plane direction. The observation that the strain-induced phase transition occurs at negative piezo voltages at lower temperature is consistent with a thermally induced built-in strain which increases with cooling.

The schematic for a strain device 300 in accordance with an embodiment of the present disclosure is shown in FIG. 3B. The van der Waals MTJ heterostructure is composed of a CrSBr tunnel barrier sandwiched between two narrow graphite contacts. The whole MTJ is fixed to a stretchable polyimide substrate by a gold clamp with a small (˜5 μm) window around the junction. This design ensures a highly efficient strain transfer when the polyimide substrate is stretched by a home-built piezoelectric strain cell, while also allowing for optical spectroscopy measurements of the junction region. The strain is applied along the crystallographic a axis. The data consistent with the present aspect is taken on a MTJ with an ≈11 nm tunnel barrier, but the technique is compatible with CrSBr flakes of any thickness.

FIG. 3C shows the TMR of a tunneling resistance device in accordance with an embodiment of the present disclosure, wherein the insulating barrier layer is an ≈11 nm CrSBr tunnel barrier (optical image inset, scale bar 3 μm) at a temperature of 60K, as a function of magnetic field (μ₀H) applied along the c axis. In the low strain condition with piezo voltage (Vₚ) of −5 V, CrSBr is in the AFM state at μ₀H=0 T. As |μ₀H| increases, the spins cant from the AFM configuration, gradually increasing the conductivity of the MTJ until it reaches the field-induced FM state with |μ₀H|>1 T. This behavior is consistent with the in-plane A-type layered AFM order in CrSBr. The saturating field is lower than standard exfoliated CrSBr samples due to a built-in strain which was estimated to be ≈0.9 % from the Raman spectra, as demonstrated in FIGS. 11A-11C.

FIG. 11A shows Raman scattering from a phonon mode at an energy ˜342 cm⁻¹ (the P₃ phonon) taken on the insulating barrier layer at a piezo voltage of 0 V. A linear background originating from the flexible polyimide substrate PL is subtracted. The narrow linewidth indicates a homogenous strain. FIG. 11B depicts a Raman intensity plot as a function of piezo voltage. The beam spot is kept on the junction as the piezo voltage is continually increased. FIG. 11C shows the measured strain as a function of the applied voltage to the strain cell. The strain is calculated by fitting the data from FIG. 11B with Lorentzian fits and then comparing the peak position to the unstrained value of 346 cm⁻¹ using a strain shift rate of 4.2 cm⁻¹/% as reported in previous studies. There was a built-in strain of ˜0.9 % at the lowest piezo voltage used at this temperature.

Using the difference in resistance between the FM (Rₚ) and AFM (Rₐₚ) states, the TMR ratio was calculated to be TMR (%)=(R_{AP}−Rₚ)/Rₚ≈3100%, on par with other 2D A-type AFM tunnel junctions, albeit at much higher operating temperature.

### Example 2: Optical Measurements

The present example relates to the characterization of tunneling resistance devices through optical measurements. Optical measurements were performed using a backscattering geometry in a closed-cycle helium cryostat (OPTICOOL® by Quantum Design) with a nominal sample temperature of 60 K. An objective lens focused 632.8 nm light from a He/Ne laser to a spot size of ˜1 μm. For Raman measurements, a laser power of 200 μW was used and the collected signal was dispersed using an 1800 mm⁻¹ groove-density grating and detected by an LN-cooled charge-coupled device (CCD) with an integration time of 210 seconds. BRAGGRATE™ notch filters were used to filter out Rayleigh scattering down to ˜10 cm⁻¹. A roughly linear background originating from weak polyimide PL was subtracted to increase the accuracy of the fitting results. For PL measurements, a laser power of 50 μW focused by the same objective was used. The collected light was dispersed by a 600 mm⁻¹ groove-density grating and detected by the same CCD with a 20 second integration time.

### Example 3: Transport Measurements

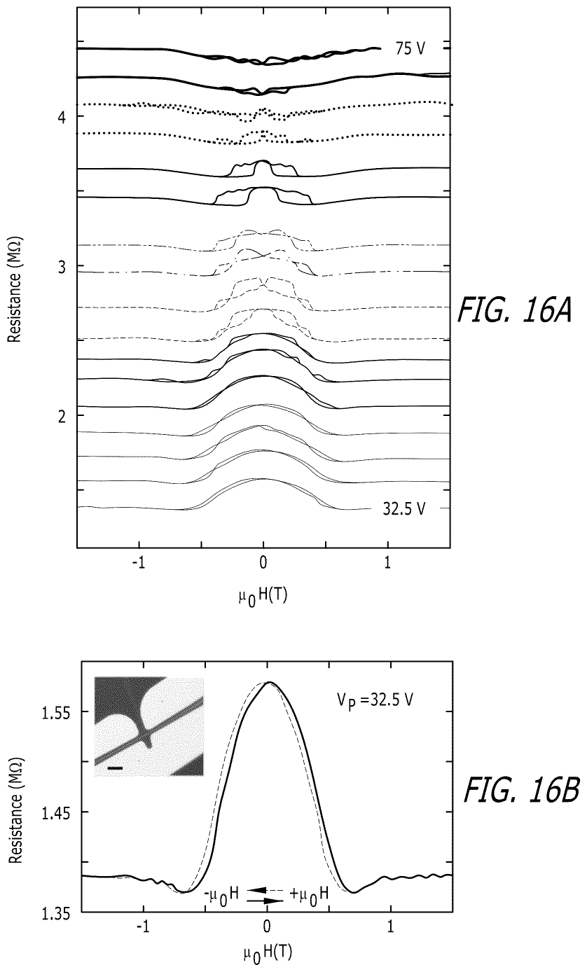

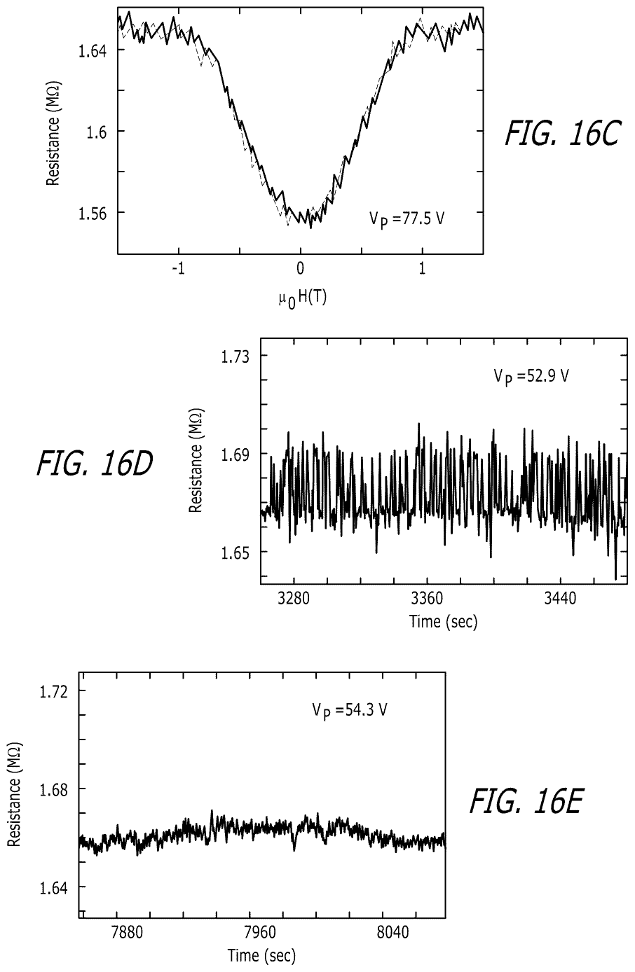

The present example relates to transport measurements through a tunneling resistance device. Except for the data presented in FIG. 16A-16E, the transport measurements were performed in the same measurement conditions (OPTICOOL® by Quantum Design, Inc.) as the optical ones, enabling direct comparison between the observed phenomena. The data shown in FIGS. 3-5 and FIG. 6B are taken using standard two terminal DC measurements with a KEITHLEY® 2450, while the data in FIGS. 6A and 6C-6G are taken using AC detection with a DC offset voltage applied by a Zurich Instruments HF2 lock-in amplifier. The current was amplified by a current preamplifier (DL Instruments, Inc. Model 1211) with a sensitivity of 1 V/10⁻⁶ A. For the switching data used in FIGS. 6E and 6F and the stochasticity analysis, a time constant of 5.082 ms with a fourth-order filter was used, which was found to give the best time resolution while maintaining a high signal to noise ratio. The current was amplified by a current preamplifier (DL Instruments, Inc. Model 1211) with a sensitivity of 1 V/10⁻⁶ A.

The 6 L device in FIG. 16 was measured in a PPMS DYNACOOL® cryostat by Quantum Design, Inc. The data in FIGS. 16A-16C were taken using the same AC detection scheme, but with an SR860 lock-in amplifier. The switching data in FIGS. 16D and 16E were obtained using a constant current measurement scheme, which was achieved by putting a 100 MΩ resistor in series with the device. The resistance signal was then pre-amplified by the differential-ended mode of SR 560 with 20 times amplification.

### Example 4: Magneto-Exciton Coupling in CRSBR

The present example relates to magneto-exciton coupling in CrSBr. Excitons dominate the optical response of 2D semiconductors due to the reduced dielectric screening and quantum confinement effects in the atomically thin limit which results in an extremely large exciton binding energy. Another consequence of the low dimensionality is that excitons in these materials are extremely sensitive to the local environment. One remarkable example is the recent use of exciton resonances in monolayer WSe₂ to sense charge-ordered states in moirë heterostructures.

Despite the success in harnessing excitons in 2D semiconductors to both realize novel devices and probe emergent fundamental physics, there have been significant challenges in exploring such physics in 2D magnets. This is because many of the prototypical 2D magnets are too insulating with Frenkel-type localized excitons (CrI₃), have small indirect band gaps (CrGeTe₃), or are metallic (Fe₃GeTe₂). Since the first discovery of magnetism in 2D CrI₃ and CrGeTe₃ flakes, there has been an explosion in the number of magnetic materials including the magnetic semiconductor CrSBr.

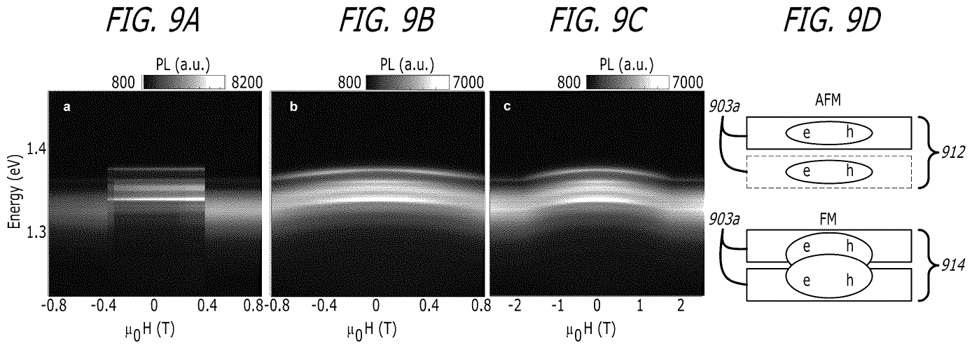

FIG. 9A shows the magneto-PL spectra of a thin bulk CrSBr flake as a magnetic field is applied along b crystal axis. At a certain value, the PL energy suddenly redshifts and then remains constant with further increasing field. On the other hand, when the field is applied along the a (FIG. 9B) or c (FIG. 9C) crystal axes, a gradual parabolic redshift is observed until the spins are polarized at a certain saturating field.

The observed behavior and saturating fields of the magneto-PL measurement agree with previous studies of the magnetic structure of CrSBr which reported easy, intermediate, and hard axes along b, a, and c, respectively. Based on first principles calculations, it was found that the magneto-exciton coupling originates from tuning of the exciton wavefunction. FIG. 9D depicts monolayers 903a in the left (solid line) and right (dashed line) aligned spin orientations. In the layered AFM interlayer coupling 912 state, the excitons are effectively localized within each layer. Aligning the spins to a layered FM interlayer coupling 914 state enables the excitons to hybridize between layers (FIG. 9D) resulting in a redshift of ˜10-15 meV. Therefore, the exciton can act as a sensor of the interlayer magnetic coupling, which can allow the direct study of the effects of external tuning parameters such as tensile strain on magnetism in CrSBr. It is worth noting that the origin of the multiple peaks and the role of defects, doping, thickness, and substrate in the CrSBr thin bulk spectrum have not yet been established, but all samples show robust magneto-exciton coupling regardless of those factors.

### Example 5: Strain Tuning of Magnetism in CRSBR

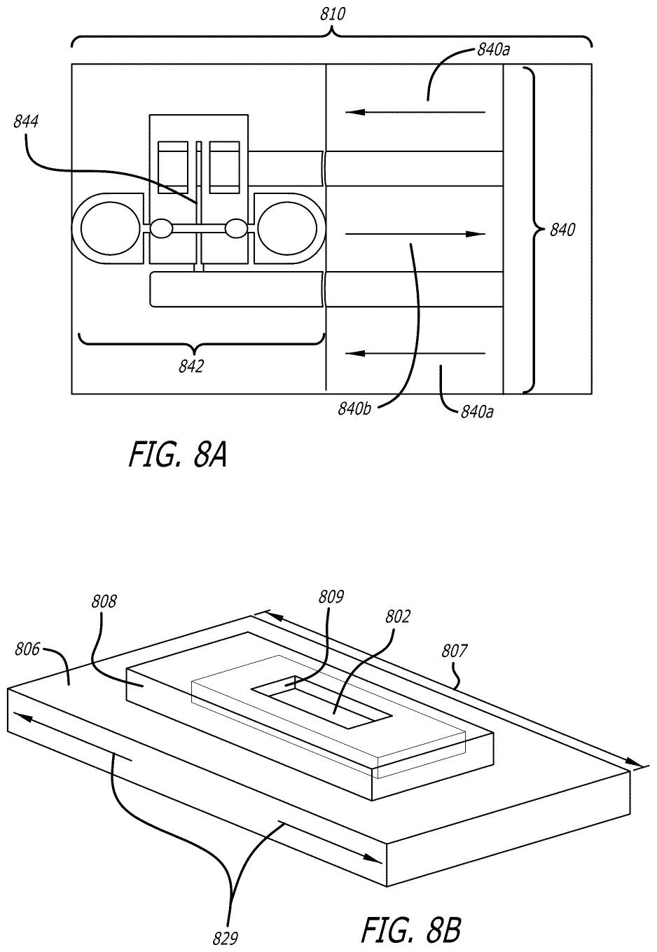

The present example relates to strain tuning of magnetism in CrSBr in a tunneling resistance device. To apply strain to thin CrSBr at cryogenic temperatures, a piezoelectric strain cell 810 was used, which has previously been utilized to strain bulk crystals, such as that depicted in FIG. 8A. In an embodiment, the piezoelectric strain cell 810 is an example of piezoelectric strain cell 210 of FIG. 2A. The cell comprises three piezo-stacks 840 which are glued to a W-shaped flexure element 842. When a positive voltage is applied, the outside stacks 840a expand while the inner stack 840b contracts, as depicted from the inset arrows, causing a gap 844 to open and tensile strain to be applied to the material which is glued across the gap 844. A benefit of this symmetric configuration is that the thermal expansion from each piezo stack 840 cancels out, resulting in negligible thermal strain from the piezo stacks 840 themselves. Since strain is proportional to the fractional change in length of the material, it is possible to achieve very large strain by making the gap 844 very small. Such an approach was used to apply large uniaxial tensile strain at cryogenic temperatures to suspended thin CrSBr in the first strain study of this material adhered to thin (50 μm) silicon wafers cut into narrow (˜300 μm) pillars. Here, strain is transferred from a flexible polyimide substrate to thin CrSBr deposited on top.

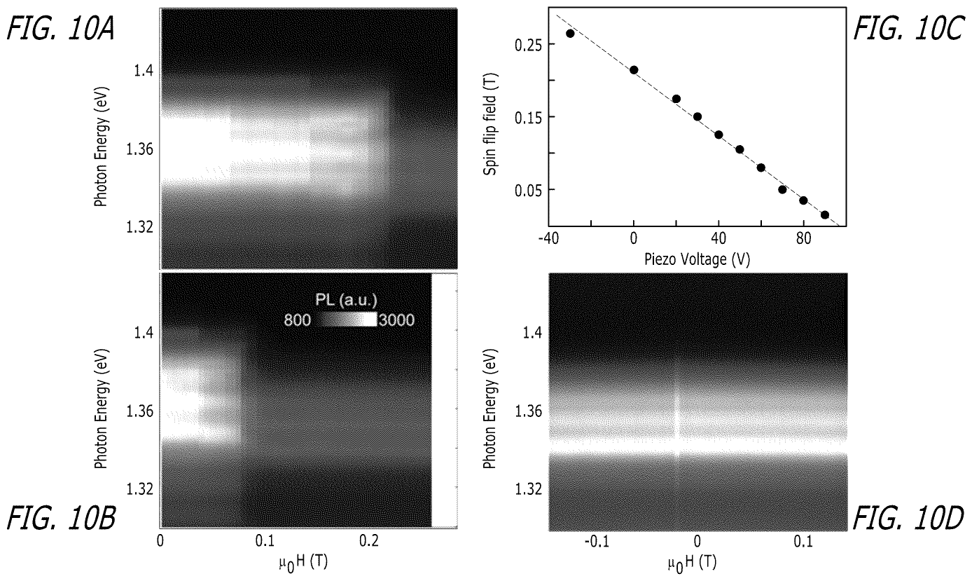

Since there tends to be a very large mismatch in Young's modulus between the 2D material and the flexible substrate, the strain transfer is very inefficient, resulting in slipping. This problem is addressed by using evaporated metals, usually gold, to clamp the material to the substrate. However, cryogenic strain experiments to date which rely on bending the flexible substrate have failed to exceed 1% in-situ tunability due to the breaking of the gold clamping contacts. In this experiment, the clamping scheme depicted in FIG. 8B is used with highly efficient strain transfer. In an embodiment, the device shown in FIG. 8B is an example of tunneling resistance device 100. Fasteners 808 clamp the insulating barrier layer 802 to the flexible substrate 806 everywhere except a small aperture 809 allowing for optical access. Two or more electrical contacts (not shown) are in electrically conductive communication with opposing sides of the insulating barrier layer 802. The tensile strain 829 is applied along the a crystal axis 807. The flake is clamped everywhere except for a small window in the center which allows for optical access. The polyimide substrate is then fixed to the piezoelectric strain cell with LOCTITE® STYCAST™ epoxy and stretched. By calibrating the applied strain through Raman spectroscopy, depicted in FIG. 10A-10D and hereinafter below, this technique enables the application of tensile strain approaching 2% to 2D materials and heterostructures at cryogenic temperatures. This increased strain range enables exciting new discoveries on emergent quantum phenomena including superconductivity, magnetism, and topology.

FIG. 10A shows magneto-PL measurements with the field applied along the easy axis of a thin bulk CrSBr on the polyimide substrate attached to the strain cell at zero piezo voltage, chosen as the nominal zero strain value. As expected, the PL exhibits a distinct red shift when the sample undergoes a spin-flip transition to the spin-polarized FM-like state. When the piezo voltage is increased to 60 V, the spin-flip field decreases dramatically (FIG. 10B). This observation is consistent with a decreasing strength of the AFM interlayer exchange. The first principles calculations reveal that strain causes a large increase in superexchange between next-nearest neighbor Cr atoms, which favors FM interaction. Due to the particular geometry of the CrSBr lattice, an in-plane strain modifies the bond angle to be closer to 90°, which strengthens FM superexchange according to the Goodenough-Kanamori-Anderson rules.

Taking magneto-PL measurements at several strains and extracting the spin-flip field reveals a linear dependence on piezo voltage (i.e., strain) until a critical threshold where it goes to zero (FIG. 10C). A linear fit gives an x-intercept of ˜91 V. This critical strain signifies the point at which the interlayer exchange changes sign and the sample undergoes a strain-induced AFM to FM phase transition. This picture is confirmed by magneto-PL measurements taken at high strain which show that the PL is invariant to field except for hysteretic brightening over a small field range, as depicted in FIG. 10D, which shows a sharp hysteretic at the coercive field of the FM state. This behavior is consistent with FM ordering: the angle between spins in adjacent layers is always zero except near the coercive field where interlayer AFM domains briefly form as the magnetization switches direction.

### Example 6: Strain Switching MTJ

The present example relates to strain switching MTJs in a tunneling resistance device. When the piezo voltage is increased, the TMR decreases dramatically, as depicted in FIG. 4A. FIG. 4A depicts magnetoresistance sweeps at select piezo voltages with a fixed bias voltage across the tunneling resistance device of V_{B}=0.5 V. The top sweep shows high tunneling resistance in the low strain (piezo voltage of −5 V and 0V) low magnetic field state, where tunneling resistance decreases with increasing magnetic field. At intermediate strain (piezo voltage of 5V) a complex hysteretic effect is seen with increasing magnetic fields. At high strain (piezo voltage of 15 V or 25 V) there is little effect of increasing magnetic fields on tunneling resistance.

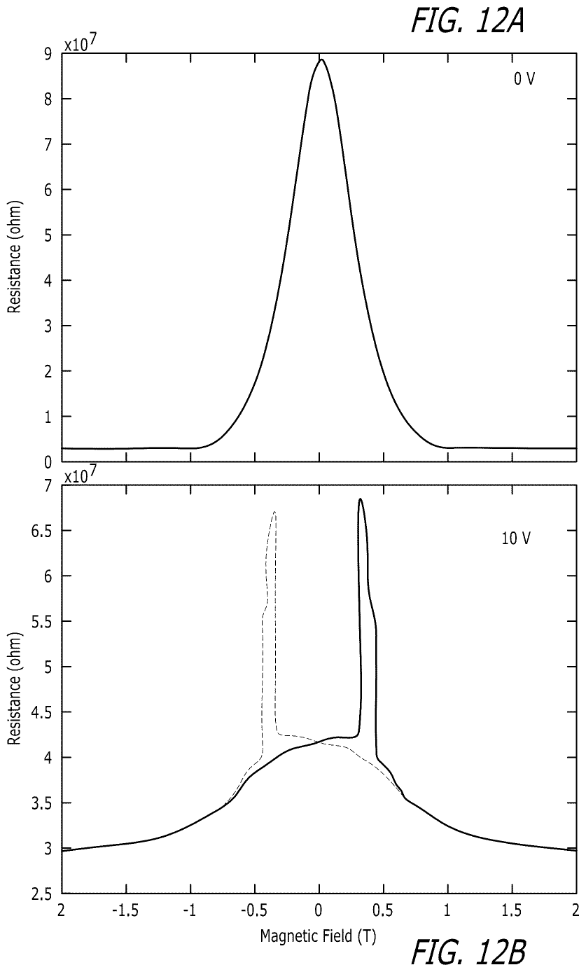

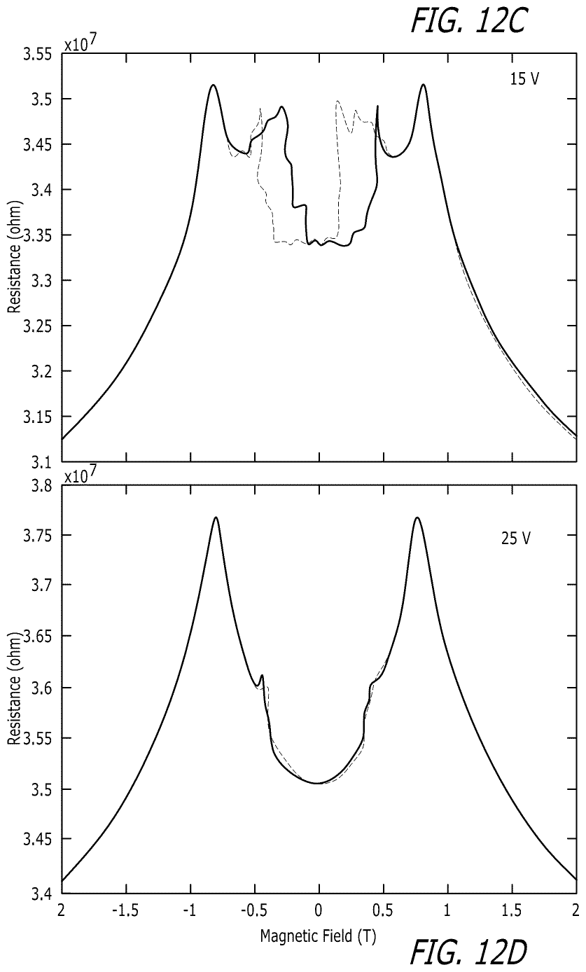

Furthermore, the shape of the TMR curves evolves from a giant, purely negative magnetoresistance (i.e., decreasing resistance with increasing field) at low strain to small positive MR at high strain, as shown in FIGS. 12A-12D, with complex, hysteretic behavior in between, e.g., the curve at 5 V in FIG. 4A. FIGS. 12A-12D depict both magnetic field down sweeps (dashed) and up sweeps (solid) at select piezo voltages arising through the strain-induced layered magnetization flipping. In the low strain state arising from the application of a piezo voltage of 0 V, depicted in FIG. 12A, for example, a large negative magnetoresistance is observed, consistent with AFM order. In the low-intermediate strain arising from the application of a piezo voltage of 10 V, depicted in FIG. 12B, peak magnetoresistance drops throughout both the up and down magnetoresistance sweep, though a complex and hysteretic magnetic domain behavior is observed in both the down (dashed) and up (solid) sweeps. In the intermediate-high strain state arising from the application of a piezo voltage of 15 V, depicted in FIG. 12C, a small positive magnetoresistance is observed with the persistence of the hysteretic magnetic domain behavior in the low-intermediate state in both the down (dashed) and up (solid) sweeps. In a high strain state arising from the application of a piezo voltage of 25 V, depicted in FIG. 12D, a small positive magnetoresistance is observed with no complex hysteretic magnetic domain behavior.

The large decrease in TMR and switching from negative to positive magnetoresistance implies that the interlayer magnetic coupling is switched from AFM to FM at large strain. This picture is confirmed by comparison of the strain-dependent PL with the magnetoresistance. In FIG. 4B, the magnetic field was swept from positive to negative, demonstrating a rapid drop-off in tunneling resistance at zero magnetic field at intermediate strain (piezo voltage of around 5 V). In FIG. 4C, PL intensity was measured with a beam spot fixed on the junction region while the strain was continuously swept. The PL shows the characteristic red shift from the strain induced AFM to FM phase transition (FIG. 4C), as demonstrated in a previous report, which is concurrent with the large changes in TMR (FIG. 4B). The close correspondence between the magneto-PL and TMR is a consequence of the coupling of spin and charge in magnetic semiconductors, which forbids or allows interlayer electronic hybridization and tunneling in the AFM and FM states, respectively.

In the low-strain state, the A-type AFM structure creates tunnel barriers composed of spin filters with alternating spin orientation. In the FM state, however, the tunnel barrier is uniform for all layers, i.e., all spin filters are aligned in the same direction. As a result, applying a saturating magnetic field at low strains strongly enhances the tunneling current with respect to the AFM state, as depicted in FIG. 4D, which shows the bias dependent tunneling current with magnetic fields of 0 T (dashed) and 3 T (solid). At high strains, however, there is little difference between the zero-and high magnetic field tunneling behavior, as expected for a FM tunnel barrier, as depicted in FIG. 4E. The combination of optical and tunneling measurements unambiguously prove that the strain-induced AFM to FM phase transition is the cause of the large TMR switching, excluding trivial origins such as contact failure during the straining process.

### Example 7: Strain Switching MTJ at Zero Magnetic Field

The present example relates to MTJs in a tunneling resistance device at zero magnetic field. Strain switching of the MTJ was realized at zero magnetic field. FIG. 5A shows the tunneling resistance as the piezo voltage is continually increased. At around 5 V, the sample experiences a switch from AFM to FM states accompanied by a sharp drop in resistance. This strain-induced phase transition generates a TMR ratio between the low and high strain states at 60 K of ≈2700 %, comparable to the magnetic field-induced TMR in the AFM state. When the tension is released, the resistance recovers to its original value. The observed hysteresis between up and down strain sweeps is likely due to a combination of the piezo stack hysteresis and hysteresis in the first-order magnetic phase transition itself. This switching operation is robust over many cycles, with no obvious slipping or degradation over the entire measurement (>50 strain sweeps).

The strain-switching operation of the MTJ persists to much higher temperature than other 2D MTJs. FIG. 5B shows TMR vs. strain cycles at 60 K, 85 K, 139 K, and 149 K. At higher temperatures, the transition between low and high TMR states becomes broader, but a large strain switching ratio is maintained. As shown in FIG. 5C, which depicts the temperature dependence of the TMR ratio, the zero-field strain-induced TMR exceeds 10,000% at 30 K and remains above 100% up to ≈140 K. Interestingly, a dome of positive magnetoresistance as a function of field can still be induced by a large strain (depicted in the dashed line of FIG. 5D) at 155 K, well above the Neel temperature of 132 K reported in previous studies, while at low strain the large negative magnetoresistance is observed (solid line). Without being bound by theory, a likely explanation is that the enhancement of the interlayer FM exchange induces a long-range ordering of the previously reported intermediate FM (iFM) phase where the individual layers are ferromagnetically ordered, but the interlayer coupling remains paramagnetic.

### Example 8: Strain Programmable Layer-Dependent Magnetism

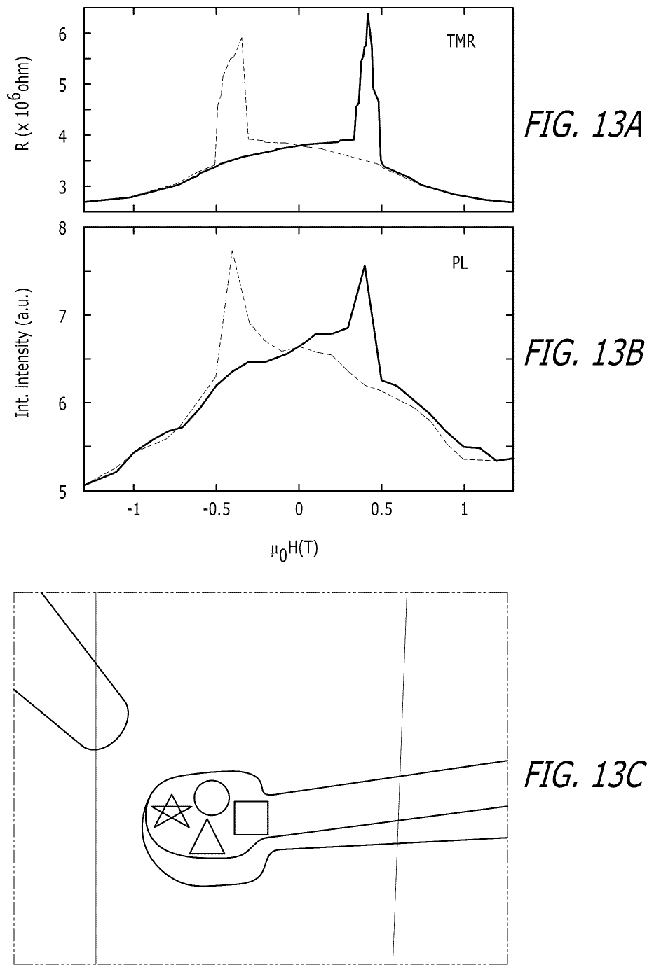

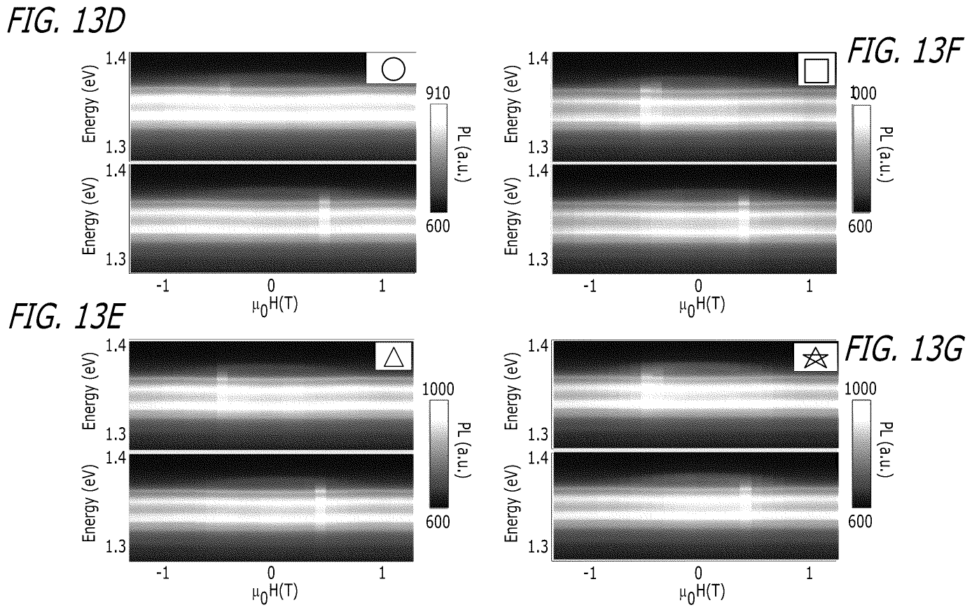

The present example relates to strain programmable layer-dependent magnetism in a tunneling resistance device. An intriguing feature of the strain-dependent TMR sweeps is that there are multiple resistance jumps during the AFM-FM phase transition, indicating the formation of multiple magnetic domains in the junction area of about 500×500 nm². These domains are also evident from the complex, hysteretic behavior observed in the field dependent TMR measurements, such as that for 5 V line of FIG. 4A. Similar magnetic domain behavior is observed in both the nanoscale junction region and across several microns of the sample in magneto-PL, as depicted in FIG. 13A-13G.

TMR measurements and magneto-PL measurements at the same piezo voltage are depicted in FIGS. 13A and 13B, corresponding to the low-intermediate strain as depicted in FIG. 12B detailed further herein above. The field is swept down (dashed) and up (solid), resulting in a complex and hysteretic magnetic domain behavior. The correlation of the curves in FIGS. 13A and 13B highlight the connection of the interlayer magnetic coupling to both electronic tunneling and exciton luminescence. Beam spots are placed at four different locations (circle, triangle, square, star), corresponding to the magneto-PL sweeps of FIGS. 13D, 13E, 13F, and 13G, respectively. The top panels of FIGS. 13D-13G depict the down sweep and the bottom panels depict the up sweep. The similarities between spots separated by several microns, indicated by FIGS. 13D-13G, indicate the presence of vertical, rather than lateral, magnetic domains.

These results suggest the formation of vertical instead of lateral magnetic domains during the phase transition. Without being bound by theory, the domains may arise from small vertical strain gradients. Thus, near the critical strain of the magnetic phase transition, the interlayer coupling can be FM for some layers and AFM for others. These layer-wise magnetic domains serve as individual magnetic memory states which can be precisely manipulated by strain.

To explore active control of layer magnetization flipping, the static strain is set near the phase transition and then strain pulses are applied with a small and controllable amplitude V_{PAC} (see FIG. 6A inset). The small switchable pulse voltage of amplitude V_{PAC} is applied on top of a static piezo voltage V_{PDC}. The system is initialized by slowly increasing V_{PDC} until the magnetic phase transition starts to occur. As the pulse amplitude increases, the current switching stabilizes into discrete states (denoted by the up-and down-facing arrows). Additionally, the resting current, i.e., ground state, can be changed by a sufficiently large pulse. FIG. 6A shows the tunneling current over time at 60 K as V_{PAC} is increased from 5 mV to 0.25 V. As the pulse reaches an amplitude of ≈24 mV, corresponding to a strain of only ≈0.0008 %, the amplitude of tunneling current pulses jumps into a distinctly stable state (left-most up-facing arrow in FIG. 6A). This indicates the MTJ switches between two magnetization states with the strain pulse actively flipping the magnetization direction of individual layers. Calculating the gauge factor, GF=(ΔR/R)/ε, gives an exceptionally large value of ≈3500, among the largest value reported in any system.

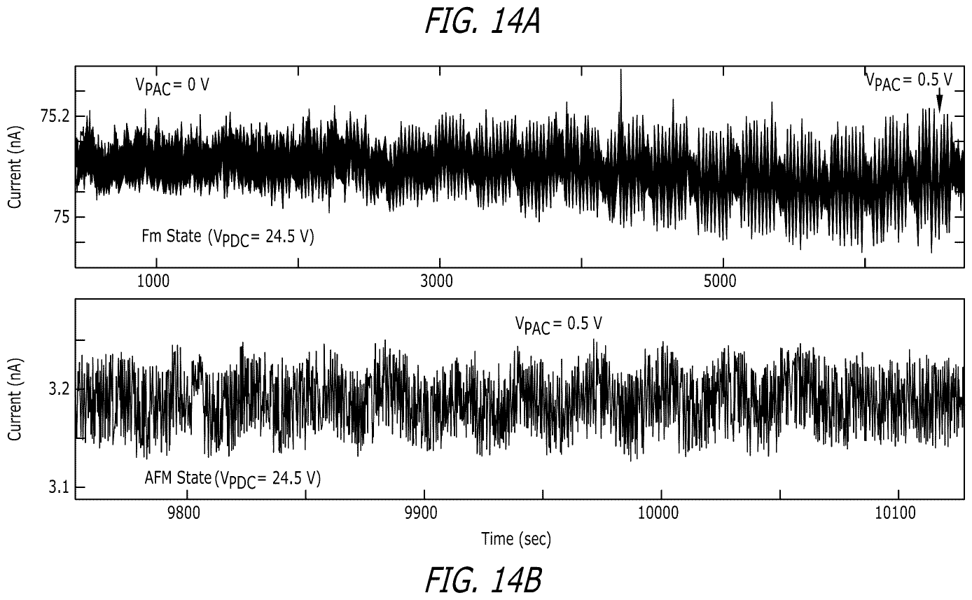

By increasing the magnitude of the strain pulse, the number of layers whose magnetization can be flipped also increases. This is evidenced by the additional distinct jumps in tunneling current with increasing pulse amplitude (down-facing arrows in FIG. 6A). With a large enough strain pulse, the static state current abruptly increases, indicating a change in the static magnetic configuration. This behavior is completely different than what is observed in the purely FM or purely AFM states, where increasing strain pulse magnitude only produces small, continuous changes at a gauge factor three orders of magnitude smaller, and with no change in the static current, as shown in FIG. 14A-14B. The purely FM state of FIG. 14A depicts that as V_{PAC} is increased from 0 to 0.5 V, a continuous change in the current is observed. The calculated gauge factor is ˜5. No changes to the static current are observed in the FM state. The purely AFM state of FIG. 14B demonstrates that, due to the very large resistance, the effect of pulses with smaller amplitude cannot be resolved. A gauge factor of ˜30 is calculated, but with a large uncertainty due to the high resistance in the AFM state. No changes to the static current are observed in the AFM state.

Therefore, the strain pulse switching observed in FIG. 6A arises from changing the vertical domain structure of the mixed magnetic states. These results demonstrate that multiple individual magnetic domains, including the static magnetic state, can be controlled by applying extremely small strain pulses.

### Example 9: Stochastic Domain Switching

The present example relates to stochastic domain switching in a tunneling resistance device. The demonstrated ability to switch the layer-dependent magnetization suggests that strain can tune the MTJ into a regime where the AFM and FM interlayer couplings are extremely close in energy. Starting from a stable magnetic domain structure at 60 K, the static strain, V_{PDC}, is increased by 14 mV, as indicated by the first and third arrows in the top panel of FIG. 6B. In such a condition, the tunneling current proceeds to fluctuate between two values, as indicated in the bottom panel of FIG. 6B, which shows a finer time resolution of the domain fluctuations observed in the top panel. By decreasing the piezo voltage by 14 mV, back to the original value (second and fourth arrows in the top panel of FIG. 6B), the tunneling current returns to a stable value. The current fluctuations can be reliably turned on and off, as demonstrated. To our knowledge, this is the first realization of p-bit type operation using a van der Waals MTJ. This functionality is enabled by the unique ability of strain to finely and continuously tune the energy barrier between parallel and anti-parallel spin configurations, enabling in-situ switching from stable, MRAM type to stochastic, p-bit type domains, shown schematically in FIG. 6C. There, a sufficiently high switchable pulse voltage, VPAC, will flip between AFM and FM domains (left panel). The fine adjustment of the static strain lowers the energy difference between AFM and FM domains, creating a metastable state with stochastic domain switching (right panel).

By defining the lower current state as a 0 and the higher current state as a 1 the data is converted to a binary sequence and the statistics of the domain switching are analyzed to determine how they respond to external control knobs, i.e., applied bias voltage and strain. Increasing the bias voltage applied to the tunnel junction at a constant piezo voltage leads to a large increase in the switching rate, as shown in FIG. 6D.

Intriguingly, no switching is observed when a current of similar magnitude flows in the opposite direction, as shown in comparing FIG. 15A (showing the tunneling current over time of a metastable domain with a positive bias applied to the MTJ tunneling resistance device) with FIG. 15B (showing the tunneling current over time of a metastable domain with a negative bias applied to the tunneling resistance device). Despite a similar magnitude of current applied to the devices in FIG. 15A and FIG. 15B, no switching is observed under negative bias. This bias-polarity dependence implies that heating is not the origin of the increased switching rate. Instead, the data suggests that the sample has an asymmetric vertical magnetic domain structure which creates a difference in spin polarization and thus spin transfer torque effects when the current is passed in opposite directions, in the manner shown schematically in FIG. 15C, which depicts a set of sixteen atomically thin monolayer planes 1503. Individual monolayers 1503a can be coupled in AFM interlayers couplings 1512 or FM interlayer couplings 1514. Without being bound by a particular theory, a plausible scenario is that when a positive voltage is applied, the FM layers polarize the tunneling electrons. These spin polarized electrons apply a spin-transfer torque like effect to the AFM layers, enhancing the stochastic switching. On the other hand, when a negative bias is applied, the electrons are not highly polarized and do not exert a spin-transfer torque on the FM layers. Whether such an asymmetric domain structure can give rise to exchange bias, magnetic ratchet effect, and other spintronics physics within a single crystal is a fascinating direction for future studies.

The relatively high Neel temperature (T_{N}=132 K) of CrSBr in comparison to other 2D A-type AFMs creates opportunities for potential device applications operating above liquid nitrogen temperature. FIG. 6E shows the response function (ρ) of the MTJ as a function of the static piezo voltage with a starting value near the strain-induced phase transition at 85 K. The response function is calculated by converting the MTJ output to a binary sequence and calculating the average over the entire time window. Therefore, a response function value of 0 or 1 indicates a stable magnetic domain, while a value of 0.5 indicates equal fluctuations between the two stable states. The ability to finely tune the response function should enable both random number generation at ρ≈0.5 and a biased Bernoulli sequence at higher or lower values, which can be useful for applications dealing with Ising and probabilistic computing. The applied bias voltage may also be used to tune the response function by increasing or decreasing the switching rate, potentially providing fine control near the edges of the sigmoidal curve, while also enabling interaction between multiple p-bits. In principle, the two independent control parameters (strain and bias voltage) offer independent tuning of the effective temperature and energy landscape of the p-bit, thereby allowing direct stochastic annealing of a p-bit system. Such a scheme significantly reduces the circuit complexity used to realize a large-scale analog p-bit annealer.

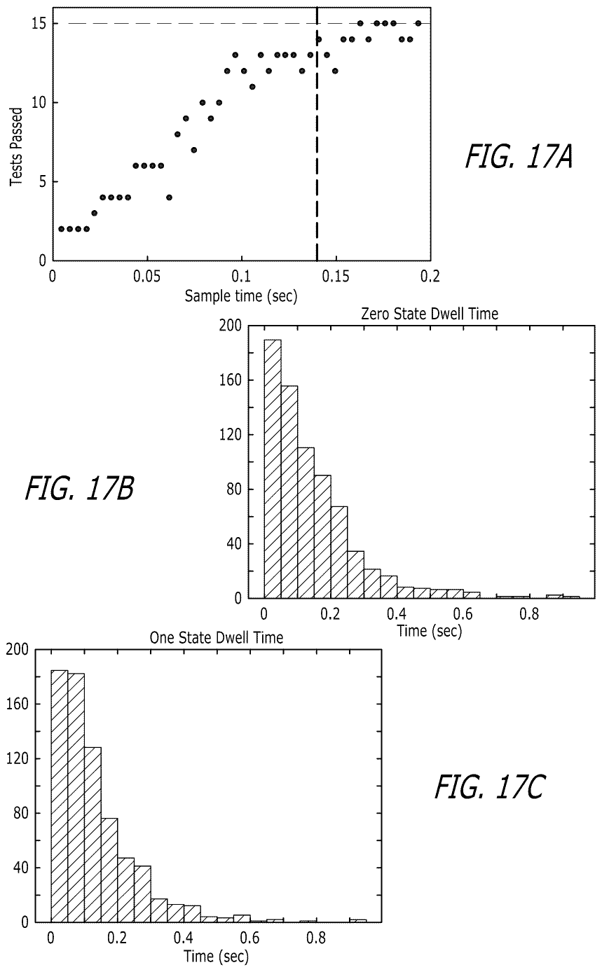

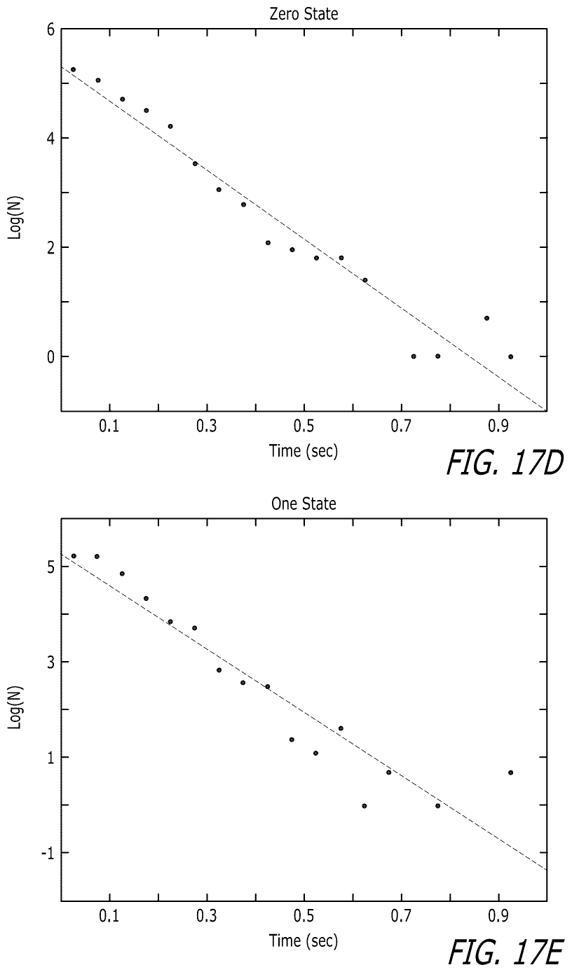

To test the stochasticity of our device, the switching data taken when ρ≈0.5 was analyzed, generating a binary sequence with near equal 1s and 0s, as shown in FIGS. 6F and 6G. The top panel of FIG. 6F shows the tunneling current over time when the response function is near 0.5, while the bottom panel shows the corresponding converted binary sequence over time when the response function is near 0.5. Since the lock-in detection scheme reads the current much faster than the domain switching rate, the raw data was sampled at a frequency which is slower than the calculated switching rate to prevent non-random runs of 1s and 0s, as demonstrated in FIGS. 17A-17E, detailed further herein below. The data was tested using the NIST test suite, shown in FIG. 6G, where the black dashed line indicates a p-value of 0.01, the threshold for passing the specific test, at a sampling time of 0.1760 seconds. Analyzing the rise and dwell time of the switching events shows that the device spends equal amounts of time in the 0 and 1 state within the experimental error (compare FIGS. 17B and 17C, and FIGS. 17D and 17E). These analyses combined with their physical origin strongly suggests that the metastable states switch stochastically, thereby acting as a random number generator.

Since the tunneling current is sampled much faster than the switching rate (˜0.14 sec), switching data collected over 200 seconds was downsampled and tested using 15 tests from the NIST test suite¹. Maurer's Universal Test was excluded since the binary sequence was not long enough. The full sampling time dependence is shown below, using a standard threshold p-value of 0.01. The horizontal dashed line indicates the sequence passed all of the 15 considered tests. The vertical dashed line indicates the average domain switching time obtained by dividing the total number of switches by the total time window.

In addition to the NIST test suite, the dwell time, i.e. the time between switches of the 0 and 1 states, was analyzed. The extracted dwell times are plotted as a histogram for the 0 (FIG. 17B) and 1 (FIG. 17C) states, following an exponential envelope as expected for a Poisson process. The logarithm of the histogram bin counts (N) was plotted versus the dwell time for the 0 (FIG. 17D) and 1(FIG. 17E) states. From the linear fits in FIGS. 17D and 17E, the characteristic lifetime, τ, of the 0 and 1 states was determined to be τ₀=159±9 ms and τ₁=151±9 ms, respectively, where the uncertainty is determined by the standard deviation of the linear fit. Based on this analysis and the NIST test suite results, the strained MTJ can generate binary sequences with a high degree of randomness.

### Example 10: Programmable 2D Quantum Devices

The present example relates to programmable 2D quantum devices from a tunneling resistance device. Strained single crystal CrSBr offers a powerful platform for realizing zero-field programmable spintronic devices down to the atomically thin limit as shown in FIG. 16. FIG. 16A depicts magnetoresistance sweeps of a MTJ with a six-layer CrSBr tunnel barrier, in accordance with an embodiment of the present disclosure, as the piezo voltage Vₚ is increased from 32.5 V to 75 V. The domain behavior at piezo voltages between the low strain AFM (32.5 V) and high strain FM (75 V) states is much simpler than ˜16-layer device presented in FIGS. 4A and 12A-12D, providing additional evidence that vertical, layer-dependent domains are the origin of the complex hysteretic domains behavior during the magnetic phase transition. The magnetic field is applied along the a axis at a temperature of 20 K. The experiments under either low and high strain are highlighted in FIGS. 16B and 16C respectively, and a comparison shows the characteristic switching from negative to positive TMR. The inset of FIG. 16B shows an optical image of the device (scale bar 5 μm). FIG. 16D depicts a plot of resistance over time at a select piezo voltage during the magnetic phase transition, depicting stochastic domain switching, while FIG. 16E depicts resistance over time at a select piezo voltage during the magnetic phase transition, depicting that the resistance can be stabilized by slightly increasing strain. The results of FIGS. 16D and 16E highlight the potential for extending the strain-programmable van der Waals MTJs to the 2D limit.

Due to the versatile nature of van der Waals heterostructures, these results create a new path for various other programmable 2D quantum devices. For instance, replacing the graphite contacts with superconducting ones enables field-free control of magnetic Josephson junctions and superconducting diode effects. Moreover, the ability to switch the layer-dependent magnetization and vertical magnetic domain structure creates unprecedented opportunities to precisely vary the length of the FM and AFM tunnel barriers in-situ without significantly changing the overall thickness of the insulating CrSBr barrier layer.

This capability provides a new platform for exploring exotic phenomena that have been proposed in superconductor/ferromagnetic junctions with inhomogeneous magnetization such as spin triplet correlations. More generally, our clamping and strain technique greatly expands the accessible strain range for cryogenic transport experiments on 2D devices, which enables exciting discoveries on the emergent quantum phenomena in van der Waals heterostructures including moiré systems.

In addition to strain, the interlayer coupling in van der Waals magnets can be tuned by twisting the layers to make moiré patterns. These structural moiré can produce moiré magnetism, an emerging field that has recently been kickstarted by the direct experimental observation of magnetic moiré patterns using diamond NV center sensing on twisted CrI₃. The fact that excitons in CrSBr are highly sensitive to the interlayer magnetic coupling raises the exciting possibility of sensing moiré magnetism. However, unlike CrI₃, CrSBr has only one stable stacking configuration and it is not yet clear what the emergent magnetic moiré pattern may be. Moreover, the large number of competing exchange interaction which contribute to the fragile interlayer exchange coupling further complicates the theoretical picture. More generally, the vast majority of moiré studies have so far focused on twisted hexagonal systems, though recent theoretical and experimental progress on orthorhombic materials has also been made.

### EMBODIMENTS

By example and without limitation, embodiments are described according to the following examples:

1. A device comprising:
an insulating barrier layer comprising a van der Waals semiconductor;
two or more electrical contacts in electrically conductive communication with opposing sides of the insulating barrier layer; and
a flexible substrate coupled to a surface of the insulating barrier layer.

2. The device of claim 1, further comprising a piezoelectric strain cell coupled with the flexible substrate, wherein the insulating barrier layer is configured to receive a tensile strain on actuation of the piezoelectric strain cell.

3. The device of claim 2, wherein the van der Waals semiconductor is configured for stochastic switching from an antiferromagnetic (AFM) interlayer coupling to a ferromagnetic (FM) interlayer coupling upon receipt of the tensile strain from the piezoelectric strain cell.

4. The device of claim 1, wherein the flexible substrate is a gapless polyimide substrate configured to stretch and thereby transfer tensile strain along a crystal axis of the insulating barrier layer.

5. The device of claim 1, wherein the van der Waals semiconductor is an A-type van der Waals antiferromagnet.

6. The device of claim 1, wherein the van der Waals semiconductor is CrSBr.

7. The device of claim 1, wherein a thickness of the insulating barrier layer is in the range of about 1.4 nm to about 20 nm.

8. The device of claim 1, wherein the insulating barrier layer comprises at least two atomically thin monolayer planes.

9. The device of any of claim 1, wherein the two or more electrical contacts comprise a superconducting electrical contact.

10. A system for inducing changes in tunneling magnetoresistance (TMR), the system comprising:
a device comprising:
an insulating barrier layer comprising a van der Waals semiconductor,
two or more electrical contacts in electrically conductive communication with opposing sides of the insulating barrier layer, and
a flexible substrate coupled to a surface of the insulating barrier layer;
a piezoelectric strain cell, wherein the device and the flexible substrate are coupled to the piezoelectric strain cell and configured to receive a tensile strain from the piezoelectric strain cell; and
a controller operatively coupled to the piezoelectric strain cell, the controller including logic that, when executed by the controller, causes the system to perform operations comprising:
applying a static voltage to the piezoelectric strain cell, thereby inducing tensile strain on the insulating barrier layer, wherein the tensile strain is sufficient to induce a switching of at least one interlayer coupling between individual monolayers of the van der Waals semiconductor from antiferromagnetic to ferromagnetic.

11. The system of claim 10, wherein the controller includes further logic that, when executed by the controller, causes the system to perform operations comprising:
applying a switchable pulse voltage to the piezoelectric strain cell, wherein the switchable pulse voltage is sufficient to stably switch at least one additional interlayer coupling between individual monolayers of the van der Waals semiconductor from antiferromagnetic to ferromagnetic.

12. The system of claim 10, wherein the static voltage is a stochastic domain switching voltage, wherein the stochastic domain switching voltage is sufficient to enable a stochastic switching of the at least one interlayer coupling between individual monolayers of the van der Waals semiconductor from antiferromagnetic to ferromagnetic.

13. The system of claim 10, wherein the controller includes further logic that, when executed by the controller, causes the system to perform operations comprising:
measuring an electrical resistance through the insulating barrier layer, wherein the interlayer coupling between monolayers of the insulating barrier layer are antiferromagnetic; and
measuring an electrical resistance through the insulating barrier layer, wherein at least one interlayer coupling between monolayers of the insulating barrier layer is ferromagnetic.

14. A method for switching an interlayer magnetic coupling from antiferromagnetic to ferromagnetic, the method comprising:
maintaining a tunneling resistance assembly at or below a switching temperature of the assembly, the tunneling resistance assembly comprising:
a tunneling resistance device, comprising:
an insulating barrier layer comprising a van der Waals semiconductor,
two or more electrical contacts in electrically conductive communication with opposing sides of the insulating barrier layer, and
a flexible substrate coupled to a surface of the insulating barrier layer; and
a piezoelectric strain cell, wherein the tunneling resistance device and the flexible substrate are fixed on the piezoelectric strain cell and configured to receive a tensile strain from the piezoelectric strain cell; and
applying a static voltage to the piezoelectric strain cell, thereby inducing tensile strain on the tunneling resistance device, wherein the static voltage is sufficient to induce switching of at least one interlayer coupling between individual monolayers of the van der Waals semiconductor from antiferromagnetic to ferromagnetic.

15. The method of claim 14, further comprising applying a switchable pulse voltage to the piezoelectric strain cell, wherein the pulse voltage is sufficient to stably switch at least one additional interlayer coupling between individual monolayers of the van der Waals semiconductor from antiferromagnetic to ferromagnetic.

16. The method of claim 14, wherein the static voltage is a stochastic domain switching voltage, wherein the stochastic domain switching voltage is sufficient to enable a stochastic switching of at least one interlayer coupling between individual monolayers of the van der Waals semiconductor from antiferromagnetic to ferromagnetic.

17. The method of claim 14, further comprising:
measuring an electrical resistance through the insulating barrier layer, wherein the interlayer coupling between monolayers of the insulating barrier layer are antiferromagnetic; and
measuring an electrical resistance through the insulating barrier layer, wherein at least one interlayer coupling between monolayers of the insulating barrier layer is ferromagnetic.

18. The method of claim 16, wherein the stochastic domain switching voltage is configured so that a response function has a value of 0.5, the method further comprising:
measuring a tunneling current amplitude value at a frequency less than a calculated stochastic magnetic domain switching frequency;
generating a tunneling current amplitude sequence from the tunneling current amplitude values; and
converting the tunneling current amplitude sequence to a binary sequence.

19. The method of claim 16, wherein the stochastic domain switching voltage is adjusted during operation, thereby operating the tunneling resistance device as an in-situ probabilistic bit.

20. The method of claim 14, wherein the switching temperature is between greater than 0 K and approximately the Neel temperature of the van der Waals semiconductor.
